(19) United States
(12) Patent Application Publication
(10) Pub. No.: US 2024/0395961 A1
(43) Pub. Date: Nov. 28, 2024

(54) PHOTODETECTION DEVICE, IMAGING DEVICE, AND DISTANCE MEASUREMENT APPARATUS

(71) Applicant: Sony Semiconductor Solutions Corporation, Kanagawa (JP)

(72) Inventors: Shohei Shimada, Kanagawa (JP); Mutsumi Okazaki, Kanagawa (JP); Satoru Yoshida, Tokyo (JP)

(21) Appl. No.: 18/687,589

(22) PCT Filed: Oct. 14, 2022
(86) PCT No.: PCT/JP22/38476

§ 371 Date: Feb. 28, 2024

(30) Foreign Application Priority Data
Oct. 21, 2021 (WO) PCT/JP2021/038918

(51) Int. Cl. H01L 31/107; H01L 27/146; H01L 31/02

(52) U.S. Cl. CPC H01L 31/1075; H01L 27/1463; H01L 27/14636; H01L 31/02027

(57) ABSTRACT

A photodetection device according to an aspect of the present disclosure includes a plurality of pixels arranged two-dimensionally. Each of the pixels includes: a photoelectric converter, a plurality of multipliers coupled in parallel to each other and coupled in series to the photoelectric converter, and a quench section coupled to the plurality of multipliers on a side opposite to a coupling side to the photoelectric converter.

### TECHNICAL FIELD

The present disclosure relates to a photodetection device, an imaging device, and a distance measurement apparatus.

### BACKGROUND ART

In recent years, a photodetection device using a SPAD (Single Photon Avalanche Diode) has attracted attention in the field of an image sensor, a distance measurement sensor, and the like (see, for example, Patent Literature 1).

### CITATION LIST

### Patent Literature

Patent Literature 1: Japanese Unexamined Patent Application Publication No. 2019-192903

### SUMMARY OF THE INVENTION

Incidentally, in a fully depleted SPAD, high collection efficiency of electrons is achieved by depletion of an entire region of a transfer path from a photoelectric converter to a multiplier, and furthermore, a high avalanche probability is achieved owing to an efficient rise of an electric field in the depletion region. Accordingly, the fully depleted SPAD makes it possible to achieve high PDE (Photon Detection Efficiency). On the other hand, however, if the depletion region is large, there is an issue of large variations among pixels in terms of characteristics including VBD (breakdown voltage), PDE, DT (Dead Time), etc. It is therefore desirable to provide a photodetection device, an imaging device, and a distance measurement apparatus that each make it possible to reduce variations among the pixels.

A photodetection device according to a first aspect of the present disclosure includes a plurality of pixels arranged two-dimensionally. Each of the pixels includes a photoelectric converter, a plurality of multipliers coupled in parallel to each other and coupled in series to the photoelectric converter, and a quench section coupled to the plurality of multipliers on a side opposite to a coupling side to the photoelectric converter.

An imaging device according to a second aspect of the present disclosure includes a plurality of pixels arranged two-dimensionally. Each of the pixels includes a photoelectric converter, a plurality of multipliers coupled in parallel to each other and coupled in series to the photoelectric converter, and a quench section coupled to the plurality of multipliers on a side opposite to a coupling side to the photoelectric converter.

A distance measurement apparatus according to a third aspect of the present disclosure includes a photodetection device. The photodetection device includes a plurality of pixels arranged two-dimensionally. Each of the pixels includes a photoelectric converter, a plurality of multipliers coupled in parallel to each other and coupled in series to the photoelectric converter, and a quench section coupled to the plurality of multipliers on a side opposite to a coupling side to the photoelectric converter.

In the photodetection device according to the first aspect of the present disclosure, the imaging device according to the second aspect of the present disclosure, and the distance measurement apparatus according to the third aspect of the present disclosure, the plurality of multipliers coupled in parallel to each other is coupled in series to the photoelectric converter in each of the pixels. This reduces characteristic variations among the pixels, as compared with a case where a single multiplier is provided for each of the pixels.

### BRIEF DESCRIPTION OF THE DRAWINGS

FIG. 1 is a diagram illustrating a functional block example of each pixel used in a photodetection device according to a first embodiment of the present disclosure.

FIG. 2 is a diagram illustrating a vertical cross-sectional configuration example of the pixel of FIG. 1.

FIG. 3 is a diagram illustrating a horizontal cross-sectional configuration example of the pixel of FIG. 2.

FIG. 4 is a diagram illustrating a modification example of the horizontal cross-sectional configuration of the pixel of FIG. 2.

FIG. 5 is a diagram illustrating a modification example of the horizontal cross-sectional configuration of the pixel of FIG. 2.

FIG. 6 is a diagram illustrating a modification example of the horizontal cross-sectional configuration of the pixel of FIG. 2.

FIG. 7 (A) is a diagram illustrating a cross-sectional configuration example of a light receiving substrate in a pixel according to Comparative Example A. (B) is a diagram illustrating a cross-sectional configuration example of a light receiving substrate in a pixel according to Comparative Example B.

FIG. 8 is a diagram illustrating a cross-sectional configuration example of a light receiving substrate in the pixel of FIG. 2.

FIG. 9 is a diagram illustrating a modification example of the vertical cross-sectional configuration of the pixel of FIG. 2.

FIG. 10 is a diagram illustrating a horizontal cross-sectional configuration example of the pixel of FIG. 9.

FIG. 11 is a diagram illustrating a modification example of the vertical cross-sectional configuration of the pixel of FIG. 2.

FIG. 12 is a diagram illustrating a horizontal cross-sectional configuration example of the pixel of FIG. 11.

FIG. 13 is a diagram illustrating a modification example of the horizontal cross-sectional configuration of the pixel of FIG. 3.

FIG. 14 is a diagram illustrating a modification example of the horizontal cross-sectional configuration of the pixel of FIG. 3.

FIG. 15 is a diagram illustrating a modification example of the horizontal cross-sectional configuration of the pixel of FIG. 3.

FIG. 16 is a diagram illustrating a modification example of a contact electrode coupled to each of multipliers of FIGS. 3, 10, and 12 to 15.

FIG. 17 is a diagram illustrating a modification example of the vertical cross-sectional configuration of the pixel of FIG. 2.

FIG. 18 is a diagram illustrating a horizontal cross-sectional configuration example of the pixel of FIG. 17.

FIG. 19 is a diagram illustrating a modification example of the horizontal cross-sectional configuration of the pixel of FIG. 17.

FIG. 20 is a diagram illustrating a modification example of the horizontal cross-sectional configuration of the pixel of FIG. 17.

FIG. 21 is a diagram illustrating a modification example of the horizontal cross-sectional configuration of the pixel of FIG. 17.

FIG. 22 is a diagram illustrating a modification example of the vertical cross-sectional configuration of the pixel of FIG. 2.

FIG. 23 is a diagram illustrating a modification example of the vertical cross-sectional configuration of the pixel of FIG. 2.

FIG. 24 is a diagram illustrating a modification example of the vertical cross-sectional configuration of the pixel of FIG. 2.

FIG. 25 is a diagram illustrating a schematic configuration example of an imaging device according to a second embodiment of the present disclosure.

FIG. 26 is a diagram illustrating a schematic configuration example of a solid-state imaging element of FIG. 25.

FIG. 27 is a diagram illustrating a circuit configuration example of a pixel of FIG. 26 and a functional block example of a signal processor of FIG. 26.

FIG. 28 is a diagram illustrating a horizontal cross-sectional configuration example of a pixel array section of FIG. 26.

FIG. 29 is a diagram illustrating a schematic configuration example of a distance measurement apparatus according to a third embodiment of the present disclosure.

FIG. 30 is a diagram illustrating a schematic configuration example of a photodetector of FIG. 29.

FIG. 31 is a diagram illustrating a circuit configuration example of a pixel of FIG. 30 and a functional block example of a signal processor of FIG. 30.

FIG. 32 is a block diagram depicting an example of schematic configuration of a vehicle control system.

FIG. 33 is a diagram of assistance in explaining an example of installation positions of an outside-vehicle information detecting section and an imaging section.

### MODES FOR CARRYING OUT THE INVENTION

In the following, some embodiments of the present disclosure will be described in detail with reference to the drawings. It is to be noted that the description will be given in the following order.

### 1. First Embodiment

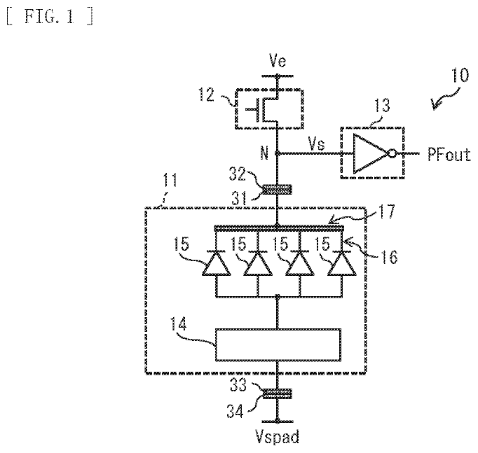

An example in which a plurality of multipliers is provided for each pixel (FIGS. 1 to 8)

### 2. Modification Examples

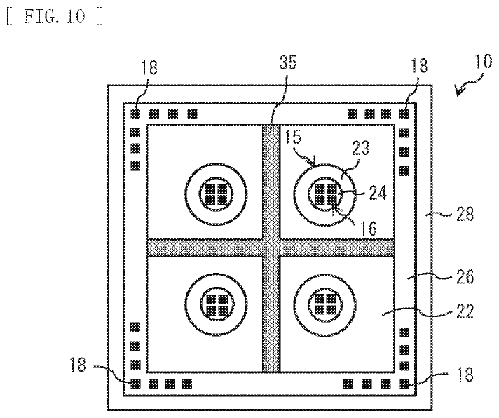

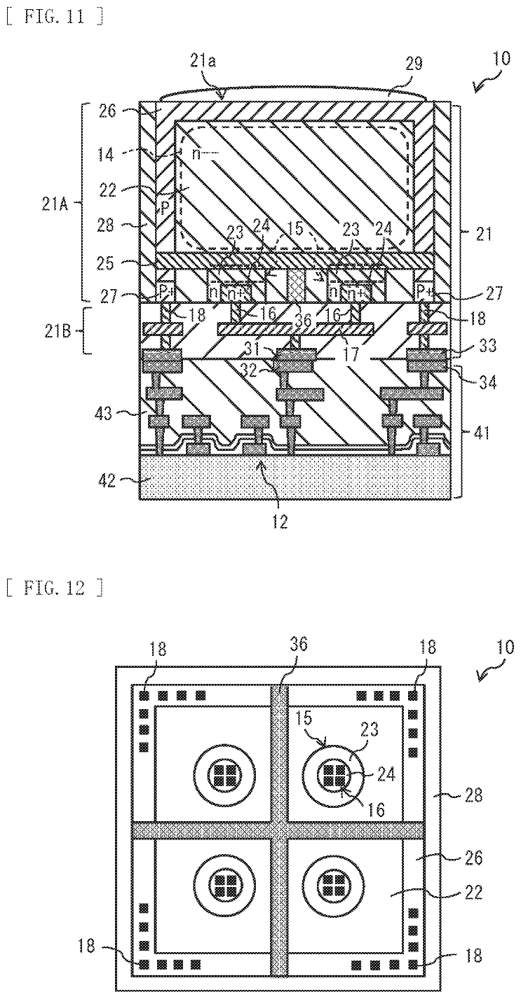

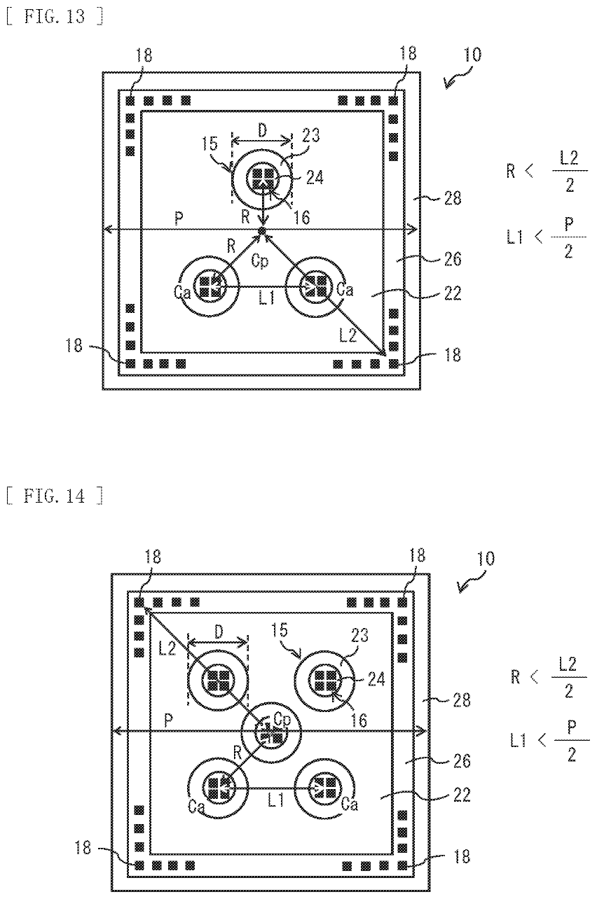

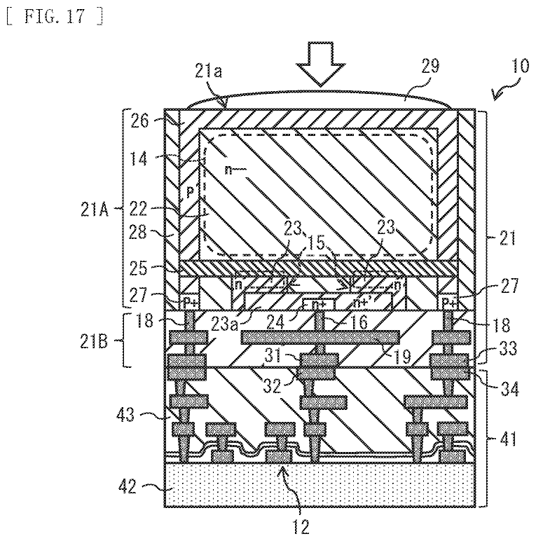

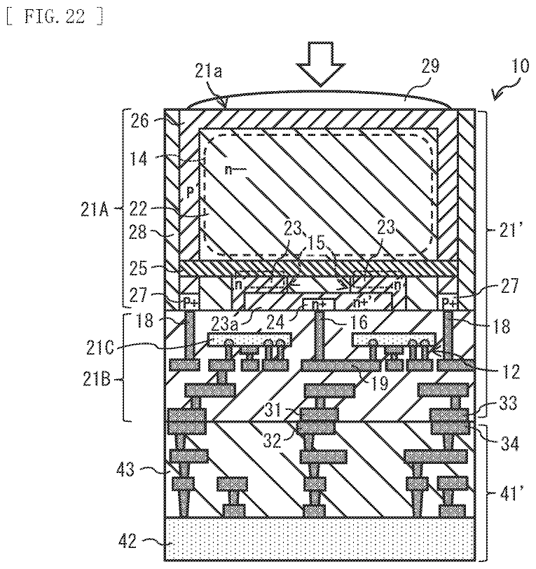

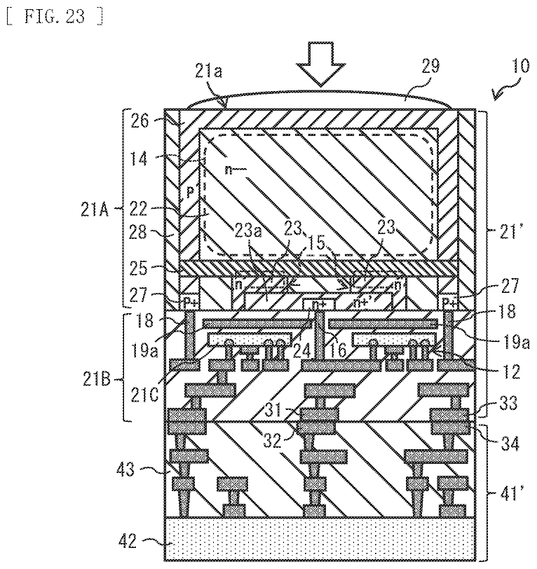

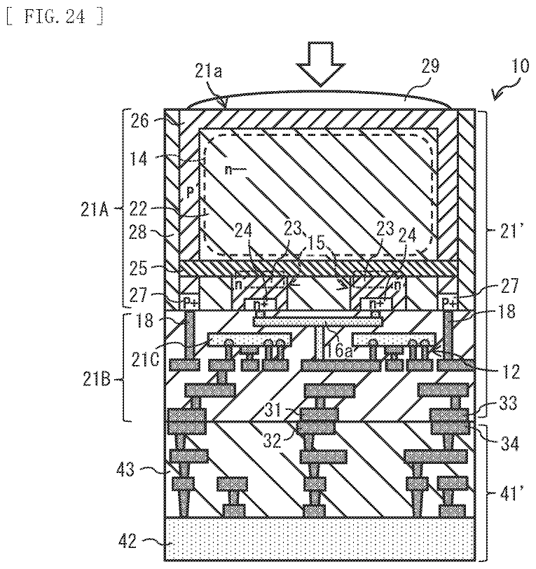

Modification Example A: an example in which an ion implant is used for separation between the multipliers (FIGS. 9 and 10)
Modification Example B: an example in which STI is used for separation between the multipliers (FIGS. 11 and 12)
Modification Example C: an example in which three, five, or nine multipliers are provided for each pixel (FIGS. 13 to 15)
Modification Example D: variations of a contact coupled to the multiplier (FIG. 16)
Modification Example E: an example in which each of the plurality of multipliers is coupled in an n-type semiconductor region (FIGS. 17 to 21)
Modification Example F: an example in which a quench section is provided on a light receiving substrate side (FIG. 22)
Modification Example G: an example in which a metal layer is provided on the light receiving substrate side (FIG. 23)
Modification Example H: an example in which a polysilicon resistor wiring line is provided (FIG. 24)
Modification Example I: variations of electrical conduction type of an impurity semiconductor

### 3. Second Embodiment

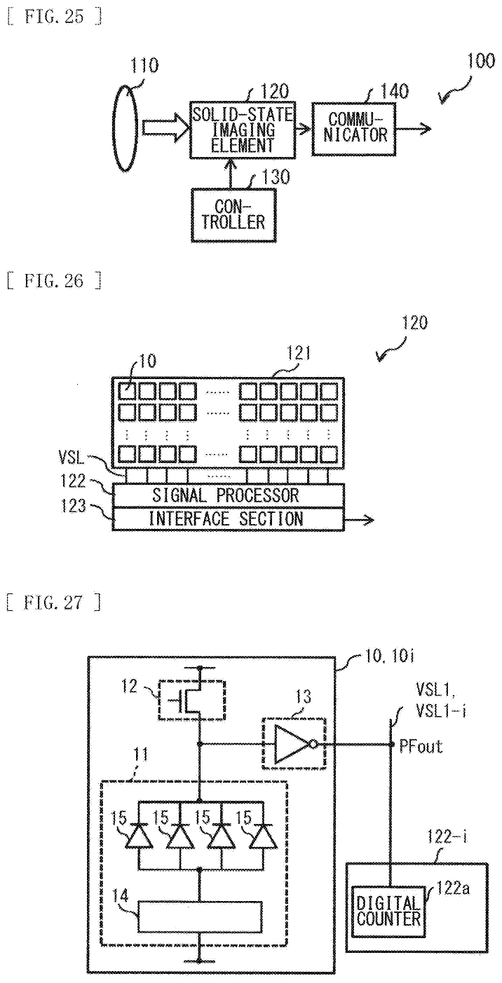

An example in which the pixels according to the above-described embodiment are used in an imaging device (FIGS. 25 to 28)

### 4. Third Embodiment

An example in which the pixels according to the above-described embodiment are used in a distance measurement apparatus (FIGS. 29 to 31)

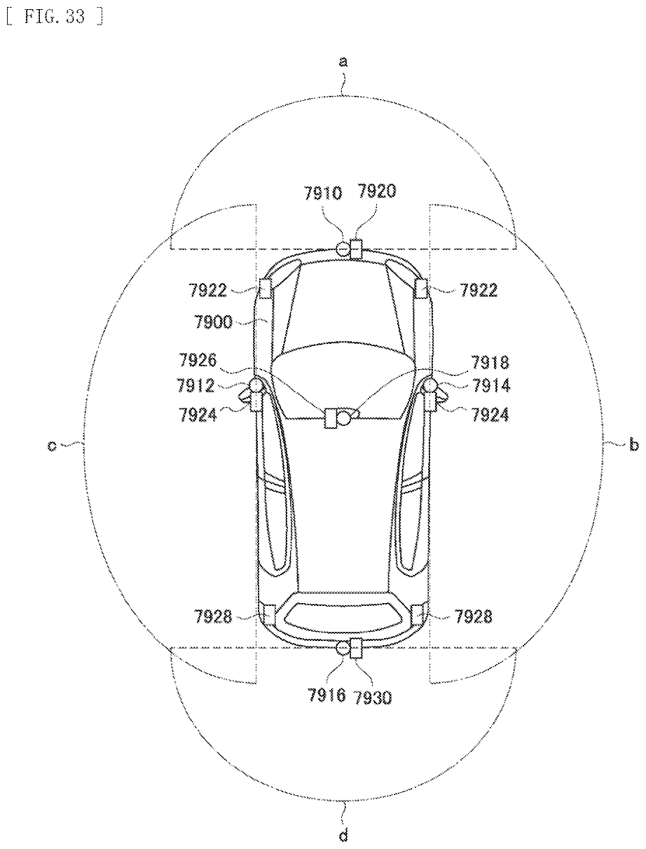

### 5. Application Example (FIGS. 32 and 33)

### 1. First Embodiment

### [Configuration]

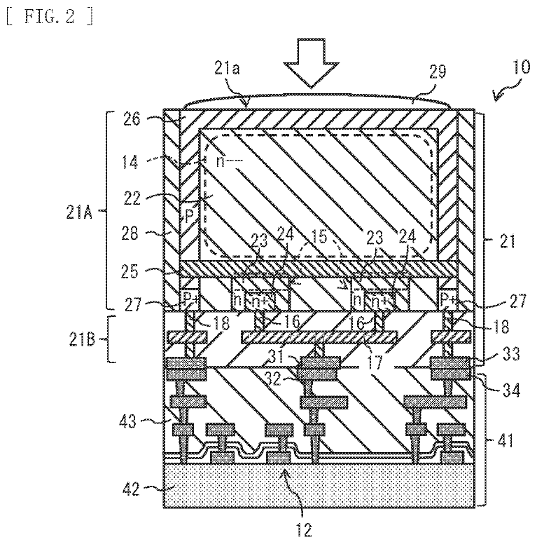

FIG. 1 illustrates a functional block example of each pixel 10 used in a photodetection device according to a first embodiment of the present disclosure (hereinafter referred to as a “photodetection device”). FIG. 2 illustrates a cross-sectional configuration example of each pixel 10. The photodetection device includes a plurality of pixels 10 arranged in a matrix form (arranged two-dimensionally). As illustrated in FIG. 1, for example, each pixel 10 includes a light receiving section 11, a quench section 12, and a detection section 13.

The light receiving section 11 generates a pulse signal in response to light incident thereon. As illustrated in FIG. 1, for example, the light receiving section 11 includes a photoelectric converter 14 and a plurality of multipliers 15. The plurality of multipliers 15 is coupled in parallel to each other and is further coupled in series to the photoelectric converter 14. As illustrated in FIG. 2, for example, the plurality of multipliers 15 is formed in a common semiconductor substrate 21A together with the photoelectric converter 14, and is coupled to the photoelectric converter 14 via impurity semiconductor regions (for example, an n-well 22 and a p-type semiconductor region 25) in the semiconductor substrate 21A. Respective portions of the plurality of multipliers 15 on a side opposite to a coupling side to the photoelectric converter 14 are electrically coupled to each other by a metal wiring line (a coupling section 17) in an interlayer insulating film 21B. The semiconductor substrate 21A includes silicon or the like. The interlayer insulating film 21B is a layer formed on top of and in contact with the semiconductor substrate 21A, and has a configuration in which a plurality of patterned wiring layers (for example, the coupling sections 17) and vias (for example, contact electrodes 16) coupling the wiring layers to each other are formed in a plurality of stacked SiO₂ layers. The semiconductor substrate 21A and the interlayer insulating film 21B constitute a light receiving substrate 21.

The light receiving section 11 includes a plurality of avalanche photodiodes (APDs) sharing the photoelectric converter 14. In the APD of a Geiger mode, when a voltage higher than or equal to a breakdown voltage is applied between terminals, an avalanche phenomenon occurs upon incidence of a single photon. The APD in which a single photon causes multiplication by the avalanche phenomenon is referred to as a single photon avalanche diode (SPAD). In each pixel 10, the light receiving section 11 includes a plurality of SPADs sharing the photoelectric converter 14, for example.

As illustrated in FIG. 1, for example, the quench section 12 is coupled to the plurality of multipliers 15 on the side opposite to the coupling side to the photoelectric converter 14. As illustrated in FIGS. 1 and 2, for example, the quench section 12 is coupled to the coupling section 17 via coupling pads 31 and 32. The quench section 12 has a function of stopping (quenching) the avalanche phenomenon by reducing the voltage applied to the light receiving section 11 to the breakdown voltage. The quench section 12 further has a function of enabling detection of a photon again at the light receiving section 11 by making the voltage applied to the light receiving section 11 into a bias voltage higher than or equal to the breakdown voltage. The quench section 12 includes a MOS transistor, for example. The quench section 12 may be a resistor, for example.

One end of the quench section 12 (for example, a source of the MOS transistor) is coupled to, for example, a power supply line to which a fixed voltage Ve is to be applied. In contrast, another end of the quench section 12 (for example, a drain of the MOS transistor) is coupled to, for example, one end of the light receiving section 11 (for example, an anode of the SAPD). Another end of the light receiving section 11 (for example, a cathode of the SAPD) is coupled to, for example, a power supply line to which a reference voltage Vspad is to be applied. Values of the fixed voltage Ve and the reference voltage Vspad are so set that a voltage higher than or equal to the breakdown voltage is applied to the light receiving section 11.

The detection section 13 is coupled to a coupling node N between the plurality of multipliers 15 and the quench section 12. The detection section 13 includes an inverter, for example. When a voltage Vs at the coupling node N is lower than a predetermined threshold voltage (that is, when the voltage Vs is at a low level Lo), the inverter outputs a signal PFout of a high level Hi. When the voltage Vs at the coupling node N is higher than or equal to the predetermined threshold voltage (that is, when the voltage Vs is at the high level Hi), the inverter outputs the signal PFout of the low level Lo. In such a manner, the detection section 13 outputs a digital signal (the signal PFout).

The detection section 13 is formed in a signal processing substrate 41. The signal processing substrate 41 is a substrate bonded to the light receiving substrate 21. The signal processing substrate 41 includes a semiconductor substrate 42 including silicon or the like, and an interlayer insulating film 43 formed on the semiconductor substrate 42. The semiconductor substrate 42 is formed in the detection section 13. The interlayer insulating film 43 is a layer formed on the semiconductor substrate 42, and has a configuration in which a plurality of patterned wiring layers and vias coupling the wiring layers to each other are formed in a plurality of stacked SiO₂ layers.

The coupling pad 31 including Cu is exposed on a surface of the light receiving substrate 21. In contrast, the coupling pad 32 including Cu is exposed on a surface of the signal processing substrate 41. The coupling pad 31 and the coupling pad 32 are joined to each other. Thus, the light receiving substrate 21 and the signal processing substrate 41 are joined to each other at the surface of the interlayer insulating film 21B and the surface of the interlayer insulating film 43, and are electrically coupled to each other by the coupling pad 31 and the coupling pad 32 being joined to each other.

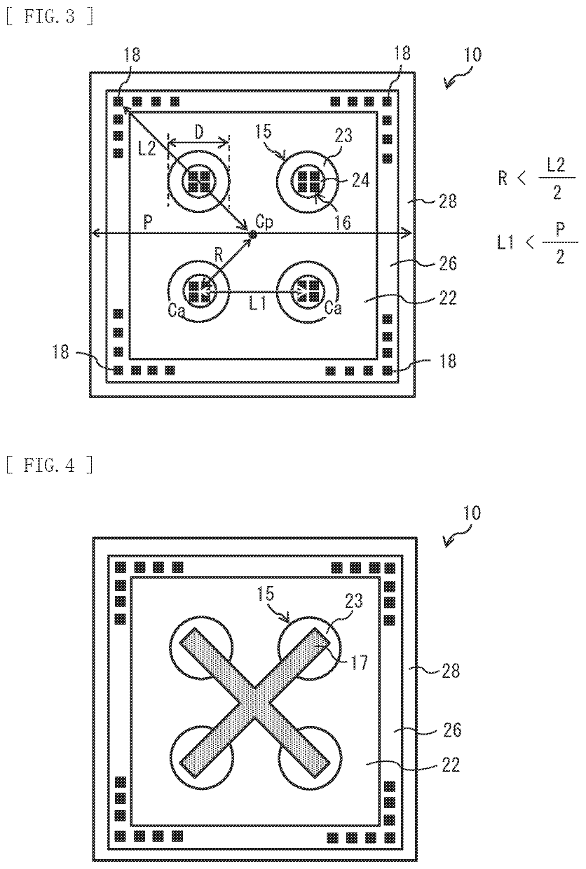

Next, a detailed description will be given of the structure of the light receiving section 11 with reference to FIGS. 2 and 3. FIG. 3 illustrates a planar configuration example of a surface (a surface on the signal processing substrate 41 side) of the semiconductor substrate 21A. Contact electrodes 16 and 18 to be described later are also illustrated in FIG. 3.

Each pixel 10 is formed in the semiconductor substrate 21A including silicon or the like. In FIG. 2, a back surface of the semiconductor substrate 21A is illustrated on an upper side of FIG. 2. An on-chip lens 29 is bonded to the back surface of the semiconductor substrate 21A. Light (incident light) from outside enters the back surface of the semiconductor substrate 21A through the on-chip lens 29. The back surface of the semiconductor substrate 21A is therefore a light receiving surface 21a. In FIG. 2, a top surface of the semiconductor substrate 21A is illustrated on a lower side of FIG. 2. The top surface of the semiconductor substrate 21A is in contact with the interlayer insulating film 21B.

As illustrated in FIG. 2, for example, each pixel 10 includes the n-well 22, a plurality of n-type semiconductor regions 23, a plurality of high-concentration n-type semiconductor regions 24, the p-type semiconductor region 25, a hole accumulation region 26, and a plurality of high-concentration p-type semiconductor regions 27. The n-well 22, the plurality of n-type semiconductor regions 23, the plurality of high-concentration n-type semiconductor regions 24, the p-type semiconductor region 25, the hole accumulation region 26, and the plurality of high-concentration p-type semiconductor regions 27 are formed in the semiconductor substrate 21A. In each pixel 10, an avalanche multiplication region (the multiplier 15) is formed by a depletion layer that is formed in a region in which the n-type semiconductor region 23 and the p-type semiconductor region 25 join to each other. That is, the multiplier 15 is formed in a pn junction region in which the n-type semiconductor region 23 and the p-type semiconductor region 25 join to each other.

The n-well 22 is formed by controlling an impurity concentration of the semiconductor substrate 21A to be of a low-concentration n-type (n−−), and produces an electric field for transferring electrons generated by photoelectric conversion in the pixel 10 to the multipliers 15. The n-well 22 serves as the photoelectric converter 14. The photoelectric converter 14 is formed in the n-well 22. The photoelectric converter 14 includes a semiconductor region of a predetermined electrical conduction type that is formed in a single region at a predetermined depth in the semiconductor substrate 21A. It is to be noted that instead of the n-well 22, a p-well may be formed in which the impurity concentration of the semiconductor-substrate 21A is controlled to be of a p-type.

The plurality of n-type semiconductor regions 23 is disposed at positions closer to a middle in a pixel region opposed to the n-well 22 (the photoelectric converter 14) in a plan view of the top surface of the semiconductor substrate 21A. Each of the n-type semiconductor regions 23 is an n-type semiconductor region of high concentration that is formed in a middle portion of the pixel 10 to a predetermined depth from a front surface side of the semiconductor substrate 21A. Of the n-type semiconductor region 23, in particular, portions in the vicinity of the front surface of the middle portion are controlled to have a high impurity concentration (n+) to constitute the high-concentration n-type semiconductor regions 24. The high-concentration n-type semiconductor regions 24 are contact sections coupled to the contact electrodes 16 as the cathodes for supplying a negative voltage for forming the multipliers 15. The fixed voltage Ve is applied from the contact electrodes 16 to the high-concentration n-type semiconductor regions 24.

The p-type semiconductor region 25 is a p-type semiconductor region of high concentration that is formed to extend over an entire surface of the pixel region in a predetermined thickness (depth) from a depth position in contact with bottom surfaces of the n-type semiconductor regions 23 in the semiconductor substrate 21A. It is to be noted that in FIG. 2, the semiconductor substrate 21A is illustrated in a manner in which a bottom surface of the semiconductor substrate 21A is on the upper side of the sheet plane and a front surface (the top surface) of the semiconductor substrate 21A is on the lower side of the sheet plane.

The p-type semiconductor region 25 is formed in a region of the semiconductor substrate 21A shallower than the photoelectric converter 14, and in contact with the photoelectric converter 14. That is, the multipliers 15 are formed in the pn junction region that is a region of the semiconductor substrate 21A shallower than the photoelectric converter 14 and formed in contact with the photoelectric converter 14. The p-type semiconductor region 25 is in contact with the photoelectric converter 14. Here, it is desirable that the impurity concentration of the n-well 22 be set to a low concentration of, for example, 1×10¹⁴ cm⁻³ or less, and that the impurity concentration of each of the n-type semiconductor regions 23 and the p-type semiconductor regions 25 forming the multipliers 15 be set to a high concentration of 1×10¹⁶ cm⁻³ or more.

The hole accumulation region 26 is a p-type semiconductor region (p) formed to surround a side surface and a bottom surface of the n-well 22, and accumulates holes generated by photoelectric conversion. The hole accumulation region 26 also has an effect of trapping electrons generated at an interface with a pixel separation section 28 and reducing a DCR (dark count rate). Regions of the hole accumulation region 26 in the vicinity of the front surface side of the semiconductor substrate 21A are controlled to have a high impurity concentration (p+) to constitute the high-concentration p-type semiconductor regions 27. The high-concentration p-type semiconductor regions 27 are contact sections coupled to the contact electrodes 16 each serving as one end of the light receiving section 11 (for example, the cathode of the SAPD). The reference voltage Vspad is applied from the contact electrodes 16 to the high-concentration p-type semiconductor regions 27. It is possible to form the hole accumulation region 26 by ion implantation. The hole accumulation region 26 may be formed by solid phase diffusion.

The pixel separation section 28 separating the pixels from each other is formed at a pixel boundary section of the pixel 10. The pixel boundary section is a boundary with an adjacent pixel. The pixel separation section 28 may include, for example, only an insulating layer such as a silicon oxide film, or may have a double structure in which an outer side (an n-well 22 side) of a metal layer such as tungsten is covered with an insulating layer such as a silicon oxide film.

As described above, in each pixel 10, regarding planar regions of the n-type semiconductor regions 23 and the p-type semiconductor region 25 in which the multipliers 15 are formed, the planar region of the p-type semiconductor region 25 is formed to be larger than the planar regions of the n-type semiconductor regions 23. Further, regarding depths of the n-type semiconductor regions 23 and the p-type semiconductor region 25 from the front surface of the semiconductor substrate 21A, the p-type semiconductor region 25 is formed to be deep relative to a depth position of the n-type semiconductor regions 23. In other words, the p-type semiconductor region 25 is formed at a position closer to the light receiving surface 21a than the n-type semiconductor regions 23.

The pixel structure of FIG. 2 is an example of a structure to read out an electron as a signal charge (carrier). However, each pixel 10 may have a structure to read out a hole. In this case, the n-type semiconductor regions 23 each having a small planar size are changed to p-type semiconductor regions, and the high-concentration n-type semiconductor regions 24 are changed to high-concentration p-type semiconductor regions. The p-type semiconductor region 25 having a large planar size is changed to an n-type semiconductor region, and the high-concentration p-type semiconductor regions 27 are changed to high-concentration n-type semiconductor regions. The reference voltage Vspad is applied from the contact electrodes 16 to the contact sections changed from the high-concentration n-type semiconductor regions 24 to the high-concentration p-type semiconductor regions, and the fixed voltage Ve is applied from the contact electrodes 18 to the contact sections changed from the high-concentration p-type semiconductor regions 27 to the high-concentration n-type semiconductor regions.

Next, a detailed description will be given of the positions of the plurality of multipliers 15 (the n-type semiconductor regions 23). As illustrated in FIG. 3, for example, four multipliers 15 (n-type semiconductor regions 23) are formed in each pixel 10. When four n-type semiconductor regions 23 are formed in each pixel 10 as in this example, the four multipliers 15 (n-type semiconductor regions 23) are disposed at positions that are closer to the middle in the pixel region opposed to the photoelectric converter 14 (the n-well 22) and, for example, that satisfy the following two relational expressions in a plan view. Moreover, in each pixel 10, the plurality of multipliers 15 (n-type semiconductor regions 23) is disposed at positions in the pixel region (the n-well 22) excluding a center (a pixel center Cp) of the pixel region. Moreover, distances R of the respective multipliers 15 may be equal to each other. However, in order to prevent two multipliers 15 adjacent to each other from interfering with each other, it is necessary for the plurality of multipliers 15 to be spaced apart from each other to some extent (for example, by about 2 μm) or more.

$$\begin{matrix}R < L 2 / 2 & ( 1 ) \\ L 1 < P / 2 & ( 2 )\end{matrix}$$

R: Distance between a center (a multiplication center Ca) of the multiplier 15 (the n-type semiconductor region 23) and the center (the pixel center Cp) of the pixel region (the n-well 22 or the photoelectric converter 14)
L1: Distance between the centers (the multiplication centers Ca) of two multipliers 15 (n-type semiconductor regions 23) adjacent to each other in a row direction or a column direction
L2: Distance between each of the contact electrodes 18 in contact with four corners of the hole accumulation region 26 and the center (the pixel center Cp) of the pixel region (the n-well 22 or the photoelectric converter 14)
P: Pixel pitch

When a plurality of contact electrodes 16 is provided for each n-type semiconductor region 23, the center (the multiplication center Ca) of the multiplier 15 (the n-type semiconductor region 23) corresponds to, for example, a middle of an electrode group including the plurality of contact electrodes 16. The pixel pitch P corresponds to, for example, a total of a length of the pixel region (the n-well 22 or the photoelectric converter 14), a width of the hole accumulation region 26, and a width of the pixel separation section 28 in a plan view in the row direction or the column direction. Although FIG. 3 illustrates an example case in which a plurality of contact electrodes 18 is formed only at the four corners of the hole accumulation region 26, the contact electrodes 18 may be formed uniformly over the hole accumulation region 26. Owing to the four multipliers 15 being disposed at the positions closer to the middle in the pixel region opposed to the pixel region, a distance from the photoelectric converter 14 to each of the multiplier 15 (a distance of a transfer path) is shortened as compared with a case where a large number of multipliers included in the plurality of pixels 10 are disposed at equal pitches in the row direction and the column direction.

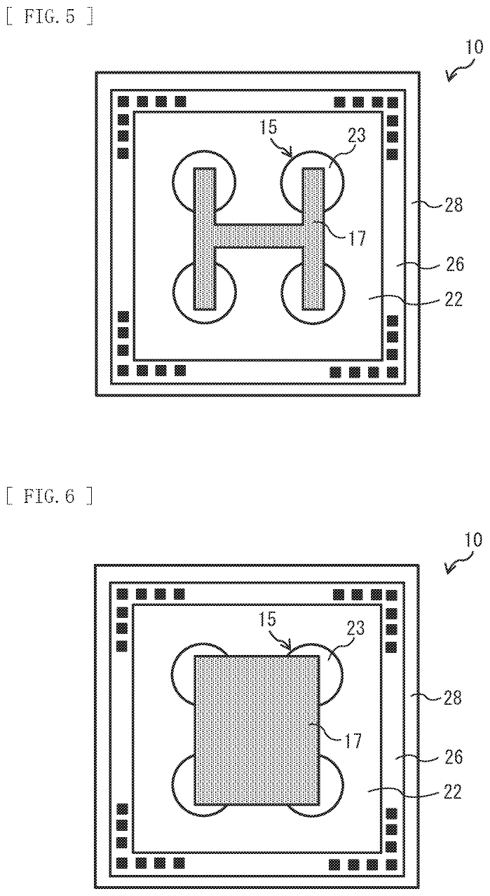

Incidentally, as illustrated in FIG. 4, for example, the coupling section 17 may include an X-shaped metal wiring line that couples the contact electrodes 16 located at two positions mutually opposed in a first diagonal direction to each other and couples the contact electrodes 16 located at two positions mutually opposed in a second diagonal direction intersecting the first diagonal direction to each other. As illustrated in FIG. 5, for example, the coupling section 17 may include an H-shaped metal wiring line that couples the contact electrodes 16 located at two right-side positions to each other and couples the contact electrodes 16 located at two left-side positions to each other. As illustrated in FIG. 6, for example, the coupling section 17 may include a rectangular metal wiring line that couples the contact electrodes 16 located at four positions to each other. When the coupling section 17 includes the rectangular metal wiring line, the coupling section 17 also serves as a mirror that reflects incident light leaking from the photoelectric converter 14 toward the photoelectric converter 14 side.

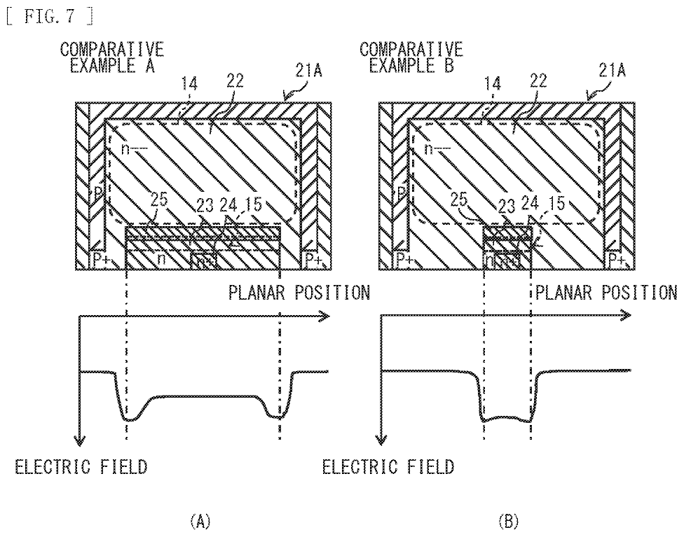

Next, the multipliers 15 in each pixel 10 will be described in comparison with a comparative example. (A) of FIG. 7 illustrates a cross-sectional configuration example of a light receiving substrate in a pixel according to Comparative Example A. (B) of FIG. 7 illustrates a cross-sectional configuration example of a pixel according to Comparative Example B.

Typically, as illustrated in an upper part of (A) of FIG. 7, the n-type semiconductor region 23 and the p-type semiconductor region 25 in which the multiplier 15 is formed are formed to have a planar size substantially the same as that of the pixel region (the n-well 22 or the photoelectric converter 14) in a plan view. However, in such a case, as illustrated in a lower part of (A) of FIG. 7, an intense electric field is produced at ends of the multiplier 15, and thus an edge breakdown occurs.

To address this, as illustrated in the upper part of (B) of FIG. 7, the n-type semiconductor region 23 and the p-type semiconductor region 25 in which the multiplier 15 is formed may be reduced in planar size to thereby form, as illustrated in the lower part of (B) of FIG. 7, the multiplier 15 that uses only portions at the ends of the multiplier 15 where the electric field is intense, and thus has an intense and uniform electric field. To form such a multiplier 15 having a uniform electric field, it is preferable that, for example, the n-type semiconductor region 23 have a diameter of 2 μm or less and that a relative distance in a depth direction of the n-type semiconductor region 23 and the p-type semiconductor region 25 be 1000 nm or less.

Accordingly, by reducing the planar size of the multiplier 15, it is possible to make the electric field uniform and prevent the edge breakdown. In the present embodiment, the p-type semiconductor region 25 is not reduced in planar size, and thus extends to the hole accumulation region 26 around the pixel.

### Effects

Next, a description will be given of effects of the photodetection device including the plurality of pixels 10.

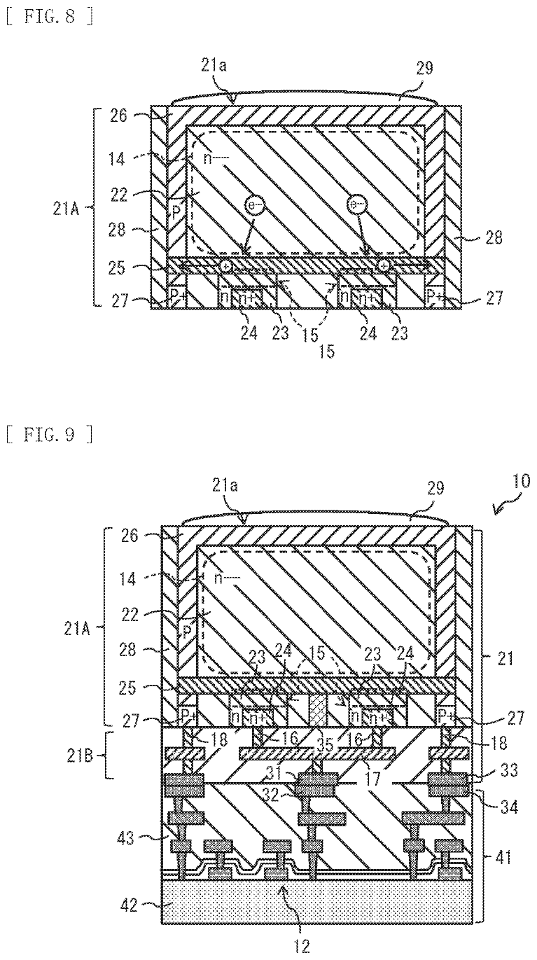

FIG. 8 illustrates a cross-sectional configuration example of the semiconductor substrate 21A in the pixel 10 according to the present embodiment. Holes generated by avalanche multiplication move to the hole accumulation region 26 via the p-type semiconductor region 25. In the p-type semiconductor region 25, a region (an outer peripheral region) located on an outer side relative to the n-type semiconductor region 23 in a plan view forms a hole current path. Thus, the outer peripheral region of the p-type semiconductor region 25 has an effect of improving an internal resistance (reducing a Hall resistance).

Further, owing to the hole current path formed by the outer peripheral region of the p-type semiconductor region 25, electrons generated in the n-well 22 (the photoelectric converter 14) by entry of incident light into the n-well 22 (the photoelectric converter 14) move to the multipliers 15 located on an inner side relative to the outer peripheral region of the p-type semiconductor region 25. That is, owing to a shielding effect by the outer peripheral region of the p-type semiconductor region 25, the electrons in the n-well 22 (the photoelectric converter 14) move to the multipliers 15 in a barrierless manner. The barrierless structure from the n-well 22 (the photoelectric converter 14) to the multipliers 15 allows for achieving high efficiency of electric charge collection.

Accordingly, the pixel 10 illustrated in FIG. 2 makes it possible to achieve high PDE while preventing edge break. Achieving the high PDE also allows for lower overbiasing.

Incidentally, in a fully depleted SPAD, high collection efficiency of electrons is achieved by depletion of an entire region of the transfer path from the photoelectric converter 14 to the multipliers 15, and furthermore, a high avalanche probability is achieved owing to an efficient rise of an electric field in the depletion region. Accordingly, the fully depleted SPAD makes it possible to achieve high PDE. On the other hand, however, if the depletion region is large, there is an issue of large variations among the pixels in terms of characteristics including VBD, PDE, DT, etc.

In contrast, according to the present embodiment, in each pixel 10, the plurality of multipliers 15 coupled in parallel to each other is coupled in series to the n-well 22 (the photoelectric converter 14). This makes it possible to reduce characteristic variations among the pixels 10 as compared with a case where a single multiplier 15 is provided for each pixel 10.

In the present embodiment, the respective portions of the plurality of multipliers 15 on the quench section 12 side are electrically coupled to each other by the metal wiring line (the coupling section 17) in the interlayer insulating film 21B. This makes it possible to reduce a wiring capacitance as compared with a case where the coupling section 17 is provided in the signal processing substrate 41. Further, in the present embodiment, in a case where the coupling section 17 includes the metal wiring line having a rectangular shape as illustrated in FIG. 6, the coupling section 17 also serves as a mirror that reflects incident light leaking from the photoelectric converter 14 toward the photoelectric converter 14 side. This makes it possible to increase quantum efficiency (QE).

In the present embodiment, the plurality of multipliers 15 is formed in the pn junction region that is a region of the semiconductor substrate 21A shallower than the photoelectric converter 14 and formed in contact with the photoelectric converter 14. This makes it possible to suppress degradation of PDE as compared with a case where separate photoelectric converters 14 are provided one for each of the multipliers 15.

In the present embodiment, the signal processing substrate 41 provided with the quench section 12 and the detection section 13 is bonded to the light receiving substrate 21. This makes it possible to minimize a length of a path for a signal outputted from the light receiving section 11 to reach the detection section 13. As a result, it is possible to reduce the wiring capacitance.

In the present embodiment, the light receiving substrate 21 and the signal processing substrate 41 are electrically coupled to each other by joining copper pads (the coupling pads 31 and 32) provided on respective joint surfaces of the light receiving substrate 21 and the signal processing substrate 41 to each other. This makes it possible to reduce the wiring capacitance.

In the present embodiment, in each pixel 10, the plurality of multipliers 15 is disposed at positions closer to the middle in the pixel region opposed to the photoelectric converter 14. This makes it possible to shorten the distance from the photoelectric converter 14 to each of the multipliers 15 as compared with a case where a large number of multipliers included in the plurality of pixels 10 are disposed at equal pitches in the row direction and the column direction. As a result, it is possible to prevent deterioration of jitter.

In the present embodiment, in each pixel 10, the plurality of multipliers 15 (n-type semiconductor regions 23) is disposed at positions in the pixel region (the n-well 22) excluding the center of the pixel region. This makes it possible to make the distances between the photoelectric converter 14 and the respective multipliers 15 substantially equal, in contrast to a case where one multiplier 15 is disposed at the center of the pixel region. Accordingly, it is possible to suppress deterioration of PDE as compared with the case where one multiplier 15 is disposed at the center of the pixel region.

### 2. Modification Examples

Next, a description will be given of modification examples of the pixels 10 according to the above-described embodiment.

### Modification Example A

In the above-described embodiment, as illustrated in FIGS. 9 and 10, for example, each pixel 10 may further include, in the same layer as the plurality of multipliers 15 in the semiconductor substrate 21A, an ion implant section 35 that separates the plurality of multipliers 15 from each other. The ion implant section 35 is formed by, for example, performing ion implantation on the n-well 22 of the semiconductor substrate 21A including silicon or the like. For example, by implanting p-type ions into the n-well 22 of the semiconductor substrate 21A, it is possible to form the ion implant section 35 that electrically separates respective cathode regions of the plurality of multipliers 15 from each other. Providing the ion implant section 35 in this way suppresses interference between the multipliers 15 adjacent to each other, thus making it possible to suppress deterioration in characteristic caused by the interference.

### Modification Example B

In the above-described embodiment, as illustrated in FIGS. 11 and 12, for example, each pixel 10 may further include, in the same layer as the plurality of multipliers 15 in the semiconductor substrate 21A, an STI (Shallow Trench Isolation) section 36 that separates the plurality of multipliers 15 from each other. The STI section 36 is formed by, for example, burying an STI structure in the n-well 22 and the hole accumulation section 26 of the semiconductor substrate 21A including silicon or the like. Providing the STI section 36 in this way suppresses interference between the multipliers 15 adjacent to each other, thus making it possible to suppress deterioration in characteristic caused by the interference.

### Modification Example C

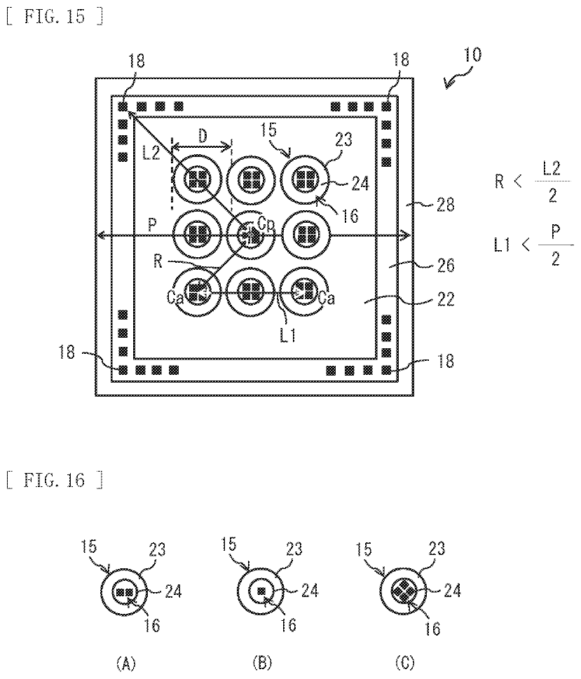

In the above-described embodiment and the modification examples thereof, three or five or more multipliers 15 (n-type semiconductor regions 23) may be formed in each pixel 10. In the above-described embodiment and the modification examples thereof, as illustrated in FIG. 13, for example, three multipliers 15 (n-type semiconductor regions 23) may be formed in each pixel 10. Alternatively, in the above-described embodiment and the modification examples thereof, as illustrated in FIG. 14, for example, five multipliers 15 (n-type semiconductor regions 23) may be formed in each pixel 10. Alternatively, in the above-described embodiment and the modification examples thereof, as illustrated in FIG. 15, for example, nine multipliers 15 (n-type semiconductor regions 23) may be formed in each pixel 10.

Assume that three multipliers 15 (n-type semiconductor regions 23) are formed in each pixel 10, as illustrated in FIG. 13, for example. In this case, the three multipliers 15 (n-type semiconductor regions 23) are disposed at positions that are closer to the middle in the pixel region opposed to the photoelectric converter 14 (the n-well 22) and, for example, that satisfy the foregoing two relational expressions (Expressions (1) and (2)) in a plan view. Moreover, in each multiplier 15, the distances R may be equal to each other. Owing to the three multipliers 15 being disposed at the positions closer to the middle in the pixel region opposed to the pixel region, the distance from the photoelectric converter 14 to each of the multipliers 15 is shortened as compared with the case where a large number of multipliers included in the plurality of pixels 10 are disposed at equal pitches in the row direction and the column direction. It is thus possible to shorten the distance from the photoelectric converter 14 to each of the multipliers 15 as compared with the case where a large number of multipliers included in the plurality of pixels 10 are disposed at equal pitches in the row direction and the column direction. As a result, it is possible to prevent deterioration of jitter.

Further, in a case where three multipliers 15 (n-type semiconductor regions 23) are formed in each pixel 10 as illustrated in, for example, FIG. 13 and where the three multipliers 15 (n-type semiconductor regions 23) are disposed at positions in the pixel region (the n-well 22) excluding the center of the pixel region, it is possible to make the distances between the photoelectric converter 14 and the respective multipliers 15 substantially equal, in contrast to a case where one multiplier 15 is disposed at the center of the pixel region. This makes it possible to suppress deterioration of PDE as compared with the case where one multiplier 15 is disposed at the center of the pixel region.

Assume that five multipliers 15 (n-type semiconductor regions 23) are formed in each pixel 10, as illustrated in FIG. 14, for example. In this case, the five multipliers 15 (n-type semiconductor regions 23) are disposed at positions that are closer to the middle in the pixel region opposed to the photoelectric converter 14 (the n-well 22) and, for example, that satisfy the foregoing two relational expressions (Expressions (1) and (2)) in a plan view. Owing to the five multipliers 15 being disposed at the positions closer to the middle in the pixel region opposed to the pixel region, the distance from the photoelectric converter 14 to each of the multipliers 15 is shortened as compared with the case where a large number of multipliers included in the plurality of pixels 10 are disposed at equal pitches in the row direction and the column direction. It is thus possible to shorten the distance from the photoelectric converter 14 to each of the multipliers 15 as compared with the case where a large number of multipliers included in the plurality of pixels 10 are disposed at equal pitches in the row direction and the column direction. As a result, it is possible to prevent deterioration of jitter.

Assume that nine multipliers 15 (n-type semiconductor regions 23) are formed in each pixel 10, as illustrated in FIG. 15, for example. In this case, the nine multipliers 15 (n-type semiconductor regions 23) are disposed at positions that are closer to the middle in the pixel region opposed to the photoelectric converter 14 (the n-well 22) and, for example, that satisfy the foregoing two relational expressions (Expressions (1) and (2)) in a plan view. Owing to the nine multipliers 15 being disposed at the positions closer to the middle in the pixel region opposed to the pixel region, the distance from the photoelectric converter 14 to each of the multipliers 15 is shortened as compared with the case where a large number of multipliers included in the plurality of pixels 10 are disposed at equal pitches in the row direction and the column direction. It is thus possible to shorten the distance from the photoelectric converter 14 to each of the multipliers 15 as compared with the case where a large number of multipliers included in the plurality of pixels 10 are disposed at equal pitches in the row direction and the column direction. As a result, it is possible to prevent deterioration of jitter.

### Modification Example D

In the above-described embodiment and the modification examples thereof, the number of the contact electrodes 16 in contact with the high-concentration n-type semiconductor region 24 of each multiplier 15 is not particularly limited. In the above-described embodiment and the modification examples thereof, as illustrated in (A) and (B) of FIG. 16, for example, the number of the contact electrodes 16 in contact with the high-concentration n-type semiconductor region 24 of each multiplier 15 may be one or two.

Further, in the above-described embodiment and the modification examples thereof, an arrangement of the plurality of contact electrodes 16 in contact with the high-concentration n-type semiconductor region 24 of each multiplier 15 is not particularly limited. In the above-described embodiment and the modification examples thereof, as illustrated in (C) of FIG. 16, for example, the contact electrodes 16 in contact with the high-concentration n-type semiconductor region 24 of each multiplier 15 may be arranged two-dimensionally in a direction intersecting the directions of arrangement of the pixels 10 (the row direction and the column direction).

### Modification Example E

In the above-described embodiment and the modification examples thereof, as illustrated in FIG. 17, for example, each pixel 10 may include an n-type semiconductor region 23a in contact with each of the plurality of multipliers 15 (specifically, the plurality of n-type semiconductor regions 23). The n-type semiconductor region 23a includes, for example, an n-type impurity having a concentration that is higher than the n-type impurity concentration of the n-type semiconductor regions 23 and lower than the n-type impurity concentration of the high-concentration n-type semiconductor region 24. The n-type semiconductor region 23a is electrically coupled to each of the plurality of n-type semiconductor regions 23.

In this case, the n-type semiconductor region 23a is also in contact with the high-concentration n-type semiconductor region 24. The n-type semiconductor region 23a is also electrically coupled to the high-concentration n-type semiconductor region 24. The number of the high-concentration n-type semiconductor regions 24 and the number of the contact electrodes 16 are each smaller than the number of the n-type semiconductor regions 23 included in one pixel 10, and are each one, for example. It is thus possible to reduce a parasitic capacitance resulting from the contact electrodes 16 by an amount corresponding to the reduction in the number of the contact electrodes 16. In addition, it is possible to suppress an increase in dark current caused by etching damage at the time of formation of the contact electrode 16 or contamination with the high-concentration n-type semiconductor region 24, by an amount corresponding to the reduction in the respective numbers of the high-concentration n-type semiconductor regions 24 and the contact electrodes 16.

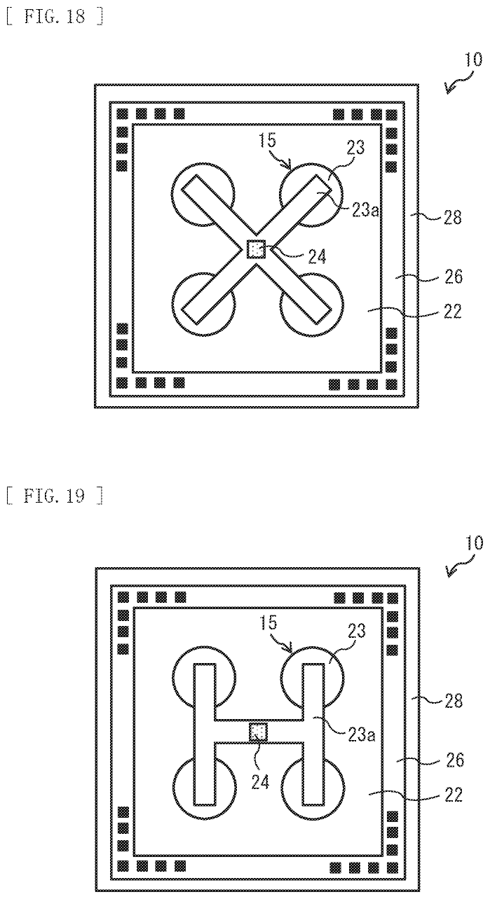

In the present modification example, the n-type semiconductor region 23a may include, as illustrated in FIG. 18, for example, an n-type semiconductor region that electrically couples the n-type semiconductor regions 23 located at two positions mutually opposed in the first diagonal direction to each other and electrically couples the n-type semiconductor regions 23 located at two positions mutually opposed in the second diagonal direction intersecting the first diagonal direction to each other. In this case, the n-type semiconductor region 23a has an X-shape in a plan view, for example. As illustrated in FIG. 18, for example, the high-concentration n-type semiconductor region 24 is in contact with a center portion (a centroid portion) of the X-shape of the n-type semiconductor region 23a.

In the present modification example, as illustrated in FIG. 19, for example, the n-type semiconductor region 23a may include an n-type semiconductor region that couples the n-type semiconductor regions 23 located at two right-side positions to each other and couples the n-type semiconductor regions 23 located at two left-side positions to each other. In this case, the n-type semiconductor region 23a has an H-shape in a plan view, for example. As illustrated in FIG. 19, for example, the high-concentration n-type semiconductor region 24 is in contact with a center portion (a centroid portion) of the X-shape of the n-type semiconductor region 23a.

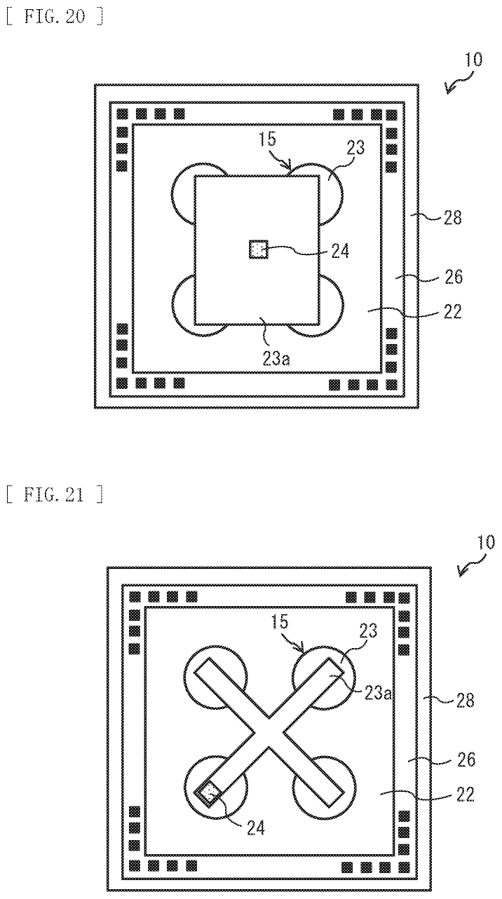

In the present modification example, as illustrated in FIG. 20, for example, the n-type semiconductor region 23a may include an n-type semiconductor region that couples the n-type semiconductor regions 23 located at four positions to each other. In this case, the n-type semiconductor region 23a has a rectangular shape in a plan view, for example. As illustrated in FIG. 20, for example, the high-concentration n-type semiconductor region 24 is in contact with a center portion (a centroid portion) of the X-shape of the n-type semiconductor region 23a.

In the present modification example, in the case where the n-type semiconductor region 23a includes the n-type semiconductor region having the X shape, the high-concentration n-type semiconductor region 24 may be in contact with one end of the X-shape of the n-type semiconductor region 23a, as illustrated in FIG. 21, for example.

In the present modification example, as illustrated in FIG. 17, for example, a metal wiring layer 19 serving as a mirror that reflects incident light leaking from the photoelectric converter 14 toward the photoelectric converter 14 side may be formed in the interlayer insulating film 21B of the light receiving substrate 21. In this case, the metal wiring layer 19 may be formed in contact with the contact electrode 16. Providing the metal wiring layer 19 in this way makes it possible to increase the quantum efficiency (QE).

### Modification Example F

In Modification Example E described above, as illustrated in FIG. 22, for example, a semiconductor substrate 21C in which a circuit such as the quench section 12 is formed may be formed in the interlayer insulating film 21B of the light receiving substrate 21. The semiconductor substrate 21C includes silicon or the like, for example. The semiconductor substrate 21C has through holes allowing the contact electrodes 16 and 18 to extend therethrough. In a case where the semiconductor substrate 21C is provided in this way, it is possible to increase an area of the circuit such as the quench section 12, as compared with a case where the circuit such as the quench section 12 is formed in the semiconductor substrate 42. In the present modification example, in a case where the metal wiring layer 19 is formed in the interlayer insulating film 21B, the metal wiring layer 19 may be used as a wiring line that electrically couples the contact electrode 16 and the semiconductor substrate 21C to each other. In the case where the metal wiring layer 19 is provided in this way, flexibility of layout of the metal wiring layer 19 increases, which makes it possible to increase the quantum efficiency (QE).

### Modification Example G

In Modification Example F described above, as illustrated in FIG. 23, for example, a metal layer 19a serving as a mirror that reflects incident light leaking from the photoelectric converter 14 toward the photoelectric converter 14 side may be formed in the interlayer insulating film 21B of the light receiving substrate 21. In this case, the metal layer 19a is preferably provided between the n-type semiconductor region 23a and the semiconductor substrate 21C. Further, the metal layer 19a may be disposed to be electrically separated from the contact electrode 16. Providing the metal wiring layer 19 in this way makes it possible to increase the quantum efficiency (QE).

It is to be noted that in the present modification example, any layer (for example, a dielectric multilayer film) serving as the mirror that that reflects incident light leaking from the photoelectric converter 14 toward the photoelectric converter 14 side may be provided instead of the metal layer 19a.

### Modification Example H

In the above-described embodiment, as illustrated in FIG. 24, for example, a polysilicon resistor wiring line 16a may be provided instead of the contact electrodes 16 and the coupling section 17. In this case, as illustrated in FIG. 24, for example, the semiconductor substrate 21C may be formed in the interlayer insulating film 21B of the light receiving substrate 21. As illustrated in FIG. 24, for example, the polysilicon resistor wiring line 16a is a wiring line that couples each of the high-concentration n-type semiconductor regions 24 and the semiconductor substrate 21C to each other. In such a case also, it is possible to obtain effects similar to those of the above-described embodiment.

### Modification Example I

In the above-described embodiment and the modification examples thereof, the electrical conduction type of the impurity semiconductor may be opposite to the above-described electrical conduction type. In the above-described embodiment and the modification examples thereof, for example, the n-well 22, the n-type semiconductor regions 23, the high-concentration n-type semiconductor regions 24, and the n-type semiconductor region 23a may each include a p-type impurity semiconductor, and the p-type semiconductor region 25, the hole accumulation region 26, and the high-concentration p-type semiconductor regions 27 may each include an n-type impurity semiconductor.

### 3. Second Embodiment

FIG. 25 is a diagram illustrating a schematic configuration example of an imaging device 100 according to a second embodiment of the present disclosure. As illustrated in FIG. 25, for example, the imaging device 100 includes an optical system 110, a solid-state imaging element 120, a controller 130, and a communicator 140.

The optical system 110 condenses incident light and guides the condensed incident light to the solid-state imaging element 120. The solid-state imaging element 120 acquires image data by imaging, and outputs the image data acquired by imaging to outside via the communicator 140. The communicator 140 is an interface that performs communications with external equipment, and outputs the image data acquired by the solid-state imaging element 120 to the external equipment.

The controller 130 controls the solid-state imaging element 120 to cause the solid-state imaging element 120 to acquire image data by imaging. For example, the controller 130 simultaneously selects a plurality of pixels 10 (a row line) disposed to be aligned in the row direction and thereby causes the solid-state imaging element 120 to hold a plurality of pieces of pixel data acquired at the selected row line. The controller 130 further causes the plurality of pieces of pixel data having been held to be outputted to the communicator 140. In such a manner, the controller 130 causes the plurality of pieces of pixel data acquired by the solid-state imaging element 120 to be outputted as image data from the solid-state imaging element 120 to the communicator 140.

FIG. 26 is a diagram illustrating a schematic configuration example of the solid-state imaging element 120 of FIG. 25. As illustrated in FIG. 26, for example, the solid-state imaging element 120 includes a pixel array section 121, a signal processor 122, and an interface section 123.

The pixel array section 121 includes the plurality of pixels 10 (hereinafter, simply referred to as “pixels 10”) according to the above-described embodiment or any of the modification examples thereof. The plurality of pixels 10 is disposed in a matrix form in an effective pixel region. In the pixel array section 121, vertical signal lines VSL are wired along the column direction for each pixel column. The vertical signal lines VSL are wiring lines for reading out signals from the pixels 10. One end of each of the vertical signal lines VSL is coupled to the signal processor 122.

The signal processor 122 generates image data on the basis of a pixel signal obtained from each of the pixels, and outputs the generated image data to the interface section 123. As illustrated in FIG. 27, for example, a readout circuit 122i is provided for each pixel column in the pixel array section 121. The “i” of “122i” corresponds to an order i (1≤i≤m) of the pixel column in the pixel array section 121. An output end of the detection section 13 is coupled to the vertical signal line VSL. The readout circuit 122i performs predetermined signal processing on the signal outputted from corresponding one of the pixels 10 through the vertical signal line VSL, and temporarily holds the pixel signal having undergone the signal processing. The signal processor 122 outputs a plurality of pixel signals having been held to the interface section 123 in order. The interface section 123 sequentially outputs, to the communicator 140, the plurality of pixel signals received from the signal processor 122.

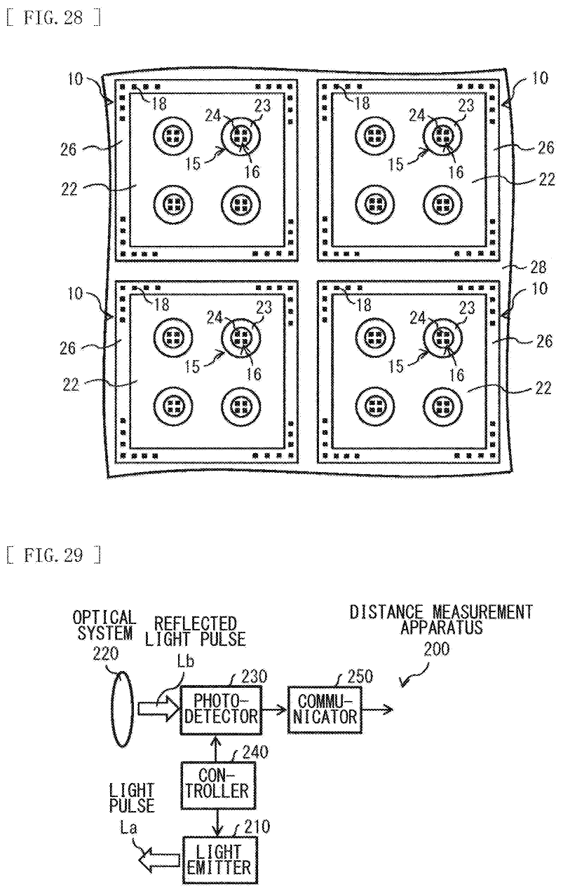

FIG. 28 illustrates a cross-sectional configuration example of the plurality of pixels 10 of the pixel array section 121. In the pixel array section 121, the plurality of pixels 10 is arranged two-dimensionally in a matrix form.

The pixel separation section 28 that separates the pixels from each other is formed at a boundary portion between two pixels 10 adjacent to each other. The pixel separation section 28 has, for example, a lattice shape, and one pixel 10 is formed in each of regions surrounded by the pixel separation section 28. In each pixel 10, the plurality of multipliers 15 is disposed at positions closer to the middle in the pixel region opposed to the photoelectric converter 14. As a result, the distance from the photoelectric converter 14 to each of the multipliers 15 is shortened as compared with the case where a large number of multipliers included in the plurality of pixels 10 are disposed at equal pitches in the row direction and the column direction.

In the present embodiment, the plurality of pixels 10 according to the above-described embodiment or any of the modification examples thereof is formed in the solid-state imaging element 120. It is thus possible obtain effects similar to those of the above-described embodiment or any of the modification examples thereof.

### 4. Third Embodiment

FIG. 29 is a diagram illustrating a schematic configuration example of a distance measurement apparatus 200 according to a third embodiment of the present disclosure. The distance measurement apparatus 200 is a ToF (Time Of Flight) sensor, and emits light to detect reflected light reflected by a detection target. As illustrated in FIG. 29, for example, the distance measurement apparatus 200 includes a light emitter 210, an optical system 220, a photodetector 230, a controller 240, and a communicator 250.

The light emitter 210 emits a light pulse La toward the detection target on the basis of instructions from the controller 240. The light emitter 210 emits the light pulse La by performing, on the basis of instructions from the controller 240, light emitting operation where light emission and non-light emission are alternately repeated. The light emitter 210 includes a light source that emits infrared light, for example. The light source includes a laser light source or an LED (Light Emitting Diode), for example.

The optical system 220 includes a lens that forms an image on a light receiving surface of the photodetector 230. A light pulse (reflected light pulse Lb) emitted from the light emitter 210 and reflected by the detection target enters the optical system 220.

The controller 240 supplies control signals to the light emitter 210 and the photodetector 230, and controls operation of the light emitter 210 and the photodetector 230 to thereby control operation of the distance measurement apparatus 200.

The photodetector 230 detects the reflected light pulse Lb on the basis of instructions from the controller 240. The photodetector 230 generates distance image data on the basis of a result of detection, and outputs the generated distance image data to outside via the communicator 140.

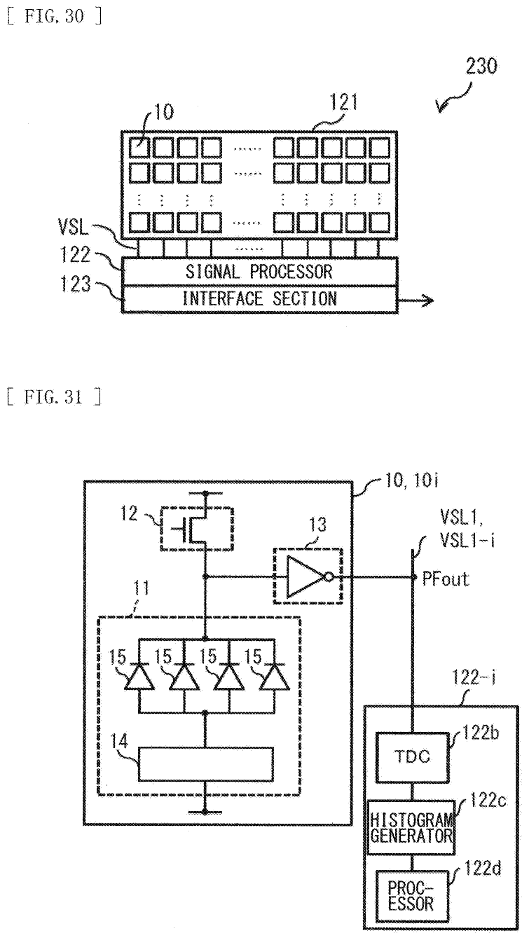

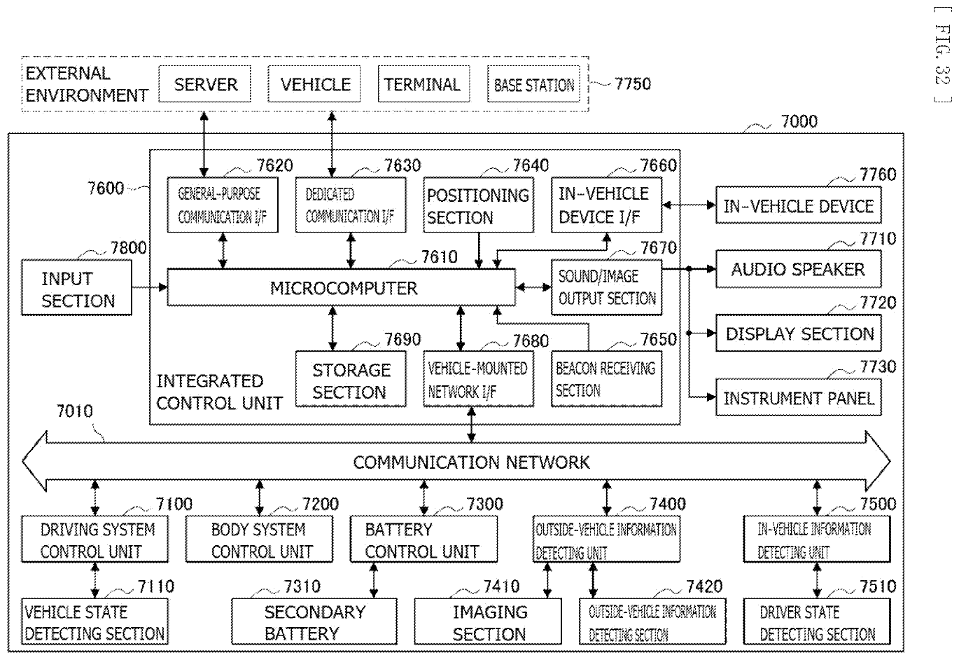

FIG. 30 is a diagram illustrating a schematic configuration example of the photodetector 230 of FIG. 29. As illustrated in FIG. 30, for example, the photodetector 230 includes the pixel array section 121, the signal processor 122, and the interface section 123.

The pixel array section 121 includes the plurality of pixels 10 (hereinafter, simply referred to as “pixels 10”) according to the above-described embodiment or any of the modification examples thereof. The plurality of pixels 10 is disposed in a matrix form in an effective pixel region. In the pixel array section 121, the vertical signal lines VSL are wired along the column direction for each pixel column. The vertical signal lines VSL are wiring lines for reading out signals from the pixels 10. One end of each of the vertical signal lines VSL is coupled to the signal processor 122.

The signal processor 122 generates image data on the basis of a pixel signal obtained from each pixel 10, and outputs the generated image data to the interface section 123. As illustrated in FIG. 30, for example, the signal processor 122 includes the readout circuit 122i for each pixel column in the pixel array section 121. The “i” of “122i” corresponds to the order i (1≤i≤m) of the pixel column in the pixel array section 121. The output end of the detection section 13 is coupled to the vertical signal line VSL. The readout circuit 122i performs predetermined signal processing on the signal outputted from corresponding one of the pixels 10 through the vertical signal line VSL, and temporarily holds the pixel signal having undergone the signal processing. The signal processor 122 outputs a plurality of pixel signals having been held to the interface section 123 in order. The interface section 123 sequentially outputs, to the communicator 140, the plurality of pixel signals received from the signal processor 122.

As illustrated in FIG. 31, for example, the readout circuit 122i includes a TDC (Time to Digital Converter) 122b, a histogram generator 122c, and a processor 122d. The TDC 122b converts a light receiving timing into a digital value on the basis of a result of detection at the pixel 10i. The histogram generator 122c generates a histogram on the basis of the digital value obtained by the TDC 122b. The processor 122d performs various kinds of processing on the basis of the histogram generated by the histogram generator 122c. For example, the processor 122d performs FIR (Finite Impulse Response) filtering processing, echo determination, depth value (distance value) calculation processing, peak detection processing, etc. The signal processor 122 generates depth image data for one frame, using the depth value obtained for each pixel 10 as the pixel signal. The signal processor 122 outputs a plurality of generated pixel signals using, for example, serial data.

In the present embodiment, the plurality of pixels 10 according to the above-described embodiment or any of the modification examples thereof is formed in the photodetector 230. It is thus possible obtain effects similar to those of the above-described embodiment or any of the modification examples thereof.

### 5. Application Example

The technology according to the present disclosure is applicable to a variety of products. For example, the technology according to the present disclosure may be implemented as a device to be mounted on any type of mobile body such as a vehicle, an electric vehicle, a hybrid electric vehicle, a motorcycle, a bicycle, a personal mobility, an airplane, a drone, a vessel, a robot, a construction machine, or an agricultural machine (tractor).

FIG. 32 is a block diagram depicting an example of schematic configuration of a vehicle control system 7000 as an example of a mobile body control system to which the technology according to an embodiment of the present disclosure can be applied. The vehicle control system 7000 includes a plurality of electronic control units connected to each other via a communication network 7010. In the example depicted in FIG. 32, the vehicle control system 7000 includes a driving system control unit 7100, a body system control unit 7200, a battery control unit 7300, an outside-vehicle information detecting unit 7400, an in-vehicle information detecting unit 7500, and an integrated control unit 7600. The communication network 7010 connecting the plurality of control units to each other may, for example, be a vehicle-mounted communication network compliant with an arbitrary standard such as controller area network (CAN), local interconnect network (LIN), local area network (LAN), FlexRay (registered trademark), or the like.

Each of the control units includes: a microcomputer that performs arithmetic processing according to various kinds of programs; a storage section that stores the programs executed by the microcomputer, parameters used for various kinds of operations, or the like; and a driving circuit that drives various kinds of control target devices. Each of the control units further includes: a network interface (I/F) for performing communication with other control units via the communication network 7010; and a communication I/F for performing communication with a device, a sensor, or the like within and without the vehicle by wire communication or radio communication. A functional configuration of the integrated control unit 7600 illustrated in FIG. 32 includes a microcomputer 7610, a general-purpose communication V/F 7620, a dedicated communication I/F 7630, a positioning section 7640, a beacon receiving section 7650, an in-vehicle device I/F 7660, a sound/image output section 7670, a vehicle-mounted network I/F 7680, and a storage section 7690. The other control units similarly include a microcomputer, a communication I/F, a storage section, and the like.

The driving system control unit 7100 controls the operation of devices related to the driving system of the vehicle in accordance with various kinds of programs. For example, the driving system control unit 7100 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like. The driving system control unit 7100 may have a function as a control device of an antilock brake system (ABS), electronic stability control (ESC), or the like.

The driving system control unit 7100 is connected with a vehicle state detecting section 7110. The vehicle state detecting section 7110, for example, includes at least one of a gyro sensor that detects the angular velocity of axial rotational movement of a vehicle body, an acceleration sensor that detects the acceleration of the vehicle, and sensors for detecting an amount of operation of an accelerator pedal, an amount of operation of a brake pedal, the steering angle of a steering wheel, an engine speed or the rotational speed of wheels, and the like. The driving system control unit 7100 performs arithmetic processing using a signal input from the vehicle state detecting section 7110, and controls the internal combustion engine, the driving motor, an electric power steering device, the brake device, and the like.

The body system control unit 7200 controls the operation of various kinds of devices provided to the vehicle body in accordance with various kinds of programs. For example, the body system control unit 7200 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 7200. The body system control unit 7200 receives these input radio waves or signals, and controls a door lock device, the power window device, the lamps, or the like of the vehicle.

The battery control unit 7300 controls a secondary battery 7310, which is a power supply source for the driving motor, in accordance with various kinds of programs. For example, the battery control unit 7300 is supplied with information about a battery temperature, a battery output voltage, an amount of charge remaining in the battery, or the like from a battery device including the secondary battery 7310. The battery control unit 7300 performs arithmetic processing using these signals, and performs control for regulating the temperature of the secondary battery 7310 or controls a cooling device provided to the battery device or the like.

The outside-vehicle information detecting unit 7400 detects information about the outside of the vehicle including the vehicle control system 7000. For example, the outside-vehicle information detecting unit 7400 is connected with at least one of an imaging section 7410 and an outside-vehicle information detecting section 7420. The imaging section 7410 includes at least one of a time-of-flight (ToF) camera, a stereo camera, a monocular camera, an infrared camera, and other cameras. The outside-vehicle information detecting section 7420, for example, includes at least one of an environmental sensor for detecting current atmospheric conditions or weather conditions and a peripheral information detecting sensor for detecting another vehicle, an obstacle, a pedestrian, or the like on the periphery of the vehicle including the vehicle control system 7000.

The environmental sensor, for example, may be at least one of a rain drop sensor detecting rain, a fog sensor detecting a fog, a sunshine sensor detecting a degree of sunshine, and a snow sensor detecting a snowfall. The peripheral information detecting sensor may be at least one of an ultrasonic sensor, a radar device, and a LIDAR device (Light detection and Ranging device, or Laser imaging detection and ranging device). Each of the imaging section 7410 and the outside-vehicle information detecting section 7420 may be provided as an independent sensor or device, or may be provided as a device in which a plurality of sensors or devices are integrated.

FIG. 33 depicts an example of installation positions of the imaging section 7410 and the outside-vehicle information detecting section 7420. Imaging sections 7910, 7912, 7914, 7916, and 7918 are, for example, disposed at least one of positions on a front nose, sideview mirrors, a rear bumper, and a back door of the vehicle 7900 and a position on an upper portion of a windshield within the interior of the vehicle. The imaging section 7910 provided to the front nose and the imaging section 7918 provided to the upper portion of the windshield within the interior of the vehicle obtain mainly an image of the front of the vehicle 7900. The imaging sections 7912 and 7914 provided to the sideview mirrors obtain mainly an image of the sides of the vehicle 7900. The imaging section 7916 provided to the rear bumper or the back door obtains mainly an image of the rear of the vehicle 7900. The imaging section 7918 provided to the upper portion of the windshield within the interior of the vehicle is used mainly to detect a preceding vehicle, a pedestrian, an obstacle, a signal, a traffic sign, a lane, or the like.

Incidentally, FIG. 33 depicts an example of photographing ranges of the respective imaging sections 7910, 7912, 7914, and 7916. An imaging range a represents the imaging range of the imaging section 7910 provided to the front nose. Imaging ranges b and c respectively represent the imaging ranges of the imaging sections 7912 and 7914 provided to the sideview mirrors. An imaging range d represents the imaging range of the imaging section 7916 provided to the rear bumper or the back door. A bird's-eye image of the vehicle 7900 as viewed from above can be obtained by superimposing image data imaged by the imaging sections 7910, 7912, 7914, and 7916, for example.

Outside-vehicle information detecting sections 7920, 7922, 7924, 7926, 7928, and 7930 provided to the front, rear, sides, and corners of the vehicle 7900 and the upper portion of the windshield within the interior of the vehicle may be, for example, an ultrasonic sensor or a radar device. The outside-vehicle information detecting sections 7920, 7926, and 7930 provided to the front nose of the vehicle 7900, the rear bumper, the back door of the vehicle 7900, and the upper portion of the windshield within the interior of the vehicle may be a LIDAR device, for example. These outside-vehicle information detecting sections 7920 to 7930 are used mainly to detect a preceding vehicle, a pedestrian, an obstacle, or the like.

Returning to FIG. 32, the description will be continued. The outside-vehicle information detecting unit 7400 makes the imaging section 7410 image an image of the outside of the vehicle, and receives imaged image data. In addition, the outside-vehicle information detecting unit 7400 receives detection information from the outside-vehicle information detecting section 7420 connected to the outside-vehicle information detecting unit 7400. In a case where the outside-vehicle information detecting section 7420 is an ultrasonic sensor, a radar device, or a LIDAR device, the outside-vehicle information detecting unit 7400 transmits an ultrasonic wave, an electromagnetic wave, or the like, and receives information of a received reflected wave. On the basis of the received information, the outside-vehicle information detecting unit 7400 may perform processing of detecting an object such as a human, a vehicle, an obstacle, a sign, a character on a road surface, or the like, or processing of detecting a distance thereto. The outside-vehicle information detecting unit 7400 may perform environment recognition processing of recognizing a rainfall, a fog, road surface conditions, or the like on the basis of the received information. The outside-vehicle information detecting unit 7400 may calculate a distance to an object outside the vehicle on the basis of the received information.

In addition, on the basis of the received image data, the outside-vehicle information detecting unit 7400 may perform image recognition processing of recognizing a human, a vehicle, an obstacle, a sign, a character on a road surface, or the like, or processing of detecting a distance thereto. The outside-vehicle information detecting unit 7400 may subject the received image data to processing such as distortion correction, alignment, or the like, and combine the image data imaged by a plurality of different imaging sections 7410 to generate a bird's-eye image or a panoramic image. The outside-vehicle information detecting unit 7400 may perform viewpoint conversion processing using the image data imaged by the imaging section 7410 including the different imaging parts.

The in-vehicle information detecting unit 7500 detects information about the inside of the vehicle. The in-vehicle information detecting unit 7500 is, for example, connected with a driver state detecting section 7510 that detects the state of a driver. The driver state detecting section 7510 may include a camera that images the driver, a biosensor that detects biological information of the driver, a microphone that collects sound within the interior of the vehicle, or the like. The biosensor is, for example, disposed in a seat surface, the steering wheel, or the like, and detects biological information of an occupant sitting in a seat or the driver holding the steering wheel. On the basis of detection information input from the driver state detecting section 7510, the in-vehicle information detecting unit 7500 may calculate a degree of fatigue of the driver or a degree of concentration of the driver, or may determine whether the driver is dozing. The in-vehicle information detecting unit 7500 may subject an audio signal obtained by the collection of the sound to processing such as noise canceling processing or the like. The integrated control unit 7600 controls general operation within the vehicle control system 7000 in accordance with various kinds of programs. The integrated control unit 7600 is connected with an input section 7800. The input section 7800 is implemented by a device capable of input operation by an occupant, such, for example, as a touch panel, a button, a microphone, a switch, a lever, or the like. The integrated control unit 7600 may be supplied with data obtained by voice recognition of voice input through the microphone. The input section 7800 may, for example, be a remote control device using infrared rays or other radio waves, or an external connecting device such as a mobile telephone, a personal digital assistant (PDA), or the like that supports operation of the vehicle control system 7000. The input section 7800 may be, for example, a camera. In that case, an occupant can input information by gesture. Alternatively, data may be input which is obtained by detecting the movement of a wearable device that an occupant wears. Further, the input section 7800 may, for example, include an input control circuit or the like that generates an input signal on the basis of information input by an occupant or the like using the above-described input section 7800, and which outputs the generated input signal to the integrated control unit 7600. An occupant or the like inputs various kinds of data or gives an instruction for processing operation to the vehicle control system 7000 by operating the input section 7800.

The storage section 7690 may include a read only memory (ROM) that stores various kinds of programs executed by the microcomputer and a random access memory (RAM) that stores various kinds of parameters, operation results, sensor values, or the like. In addition, the storage section 7690 may be implemented by a magnetic storage device such as a hard disc drive (HDD) or the like, a semiconductor storage device, an optical storage device, a magneto-optical storage device, or the like.

The general-purpose communication I/F 7620 is a communication I/F used widely, which communication I/F mediates communication with various apparatuses present in an external environment 7750. The general-purpose communication I/F 7620 may implement a cellular communication protocol such as global system for mobile communications (GSM (registered trademark)), worldwide interoperability for microwave access (WiMAX (registered trademark)), long term evolution (LTE (registered trademark)), LTE-advanced (LTE-A), or the like, or another wireless communication protocol such as wireless LAN (referred to also as wireless fidelity (Wi-Fi (registered trademark)), Bluetooth (registered trademark), or the like. The general-purpose communication I/F 7620 may, for example, connect to an apparatus (for example, an application server or a control server) present on an external network (for example, the Internet, a cloud network, or a company-specific network) via a base station or an access point. In addition, the general-purpose communication I/F 7620 may connect to a terminal present in the vicinity of the vehicle (which terminal is, for example, a terminal of the driver, a pedestrian, or a store, or a machine type communication (MTC) terminal) using a peer to peer (P2P) technology, for example.

The dedicated communication I/F 7630 is a communication I/F that supports a communication protocol developed for use in vehicles. The dedicated communication I/F 7630 may implement a standard protocol such, for example, as wireless access in vehicle environment (WAVE), which is a combination of institute of electrical and electronic engineers (IEEE) 802.11p as a lower layer and IEEE 1609 as a higher layer, dedicated short range communications (DSRC), or a cellular communication protocol. The dedicated communication I/F 7630 typically carries out V2X communication as a concept including one or more of communication between a vehicle and a vehicle (Vehicle to Vehicle), communication between a road and a vehicle (Vehicle to Infrastructure), communication between a vehicle and a home (Vehicle to Home), and communication between a pedestrian and a vehicle (Vehicle to Pedestrian).

The positioning section 7640, for example, performs positioning by receiving a global navigation satellite system (GNSS) signal from a GNSS satellite (for example, a GPS signal from a global positioning system (GPS) satellite), and generates positional information including the latitude, longitude, and altitude of the vehicle. Incidentally, the positioning section 7640 may identify a current position by exchanging signals with a wireless access point, or may obtain the positional information from a terminal such as a mobile telephone, a personal handyphone system (PHS), or a smart phone that has a positioning function.

The beacon receiving section 7650, for example, receives a radio wave or an electromagnetic wave transmitted from a radio station installed on a road or the like, and thereby obtains information about the current position, congestion, a closed road, a necessary time, or the like. Incidentally, the function of the beacon receiving section 7650 may be included in the dedicated communication I/F 7630 described above.

The in-vehicle device I/F 7660 is a communication interface that mediates connection between the microcomputer 7610 and various in-vehicle devices 7760 present within the vehicle. The in-vehicle device I/F 7660 may establish wireless connection using a wireless communication protocol such as wireless LAN, Bluetooth (registered trademark), near field communication (NFC), or wireless universal serial bus (WUSB). In addition, the in-vehicle device I/F 7660 may establish wired connection by universal serial bus (USB), high-definition multimedia interface (HDMI (registered trademark)), mobile high-definition link (MHL), or the like via a connection terminal (and a cable if necessary) not depicted in the figures. The in-vehicle devices 7760 may, for example, include at least one of a mobile device and a wearable device possessed by an occupant and an information device carried into or attached to the vehicle. The in-vehicle devices 7760 may also include a navigation device that searches for a path to an arbitrary destination. The in-vehicle device I/F 7660 exchanges control signals or data signals with these in-vehicle devices 7760.

The vehicle-mounted network I/F 7680 is an interface that mediates communication between the microcomputer 7610 and the communication network 7010. The vehicle-mounted network I/F 7680 transmits and receives signals or the like in conformity with a predetermined protocol supported by the communication network 7010.

The microcomputer 7610 of the integrated control unit 7600 controls the vehicle control system 7000 in accordance with various kinds of programs on the basis of information obtained via at least one of the general-purpose communication I/F 7620, the dedicated communication I/F 7630, the positioning section 7640, the beacon receiving section 7650, the in-vehicle device I/F 7660, and the vehicle-mounted network I/F 7680. For example, the microcomputer 7610 may calculate a control target value for the driving force generating device, the steering mechanism, or the braking device on the basis of the obtained information about the inside and outside of the vehicle, and output a control command to the driving system control unit 7100. For example, the microcomputer 7610 may perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like. In addition, the microcomputer 7610 may perform cooperative control intended for automated driving, which makes the vehicle to travel automatedly without depending on the operation of the driver, or the like, by controlling the driving force generating device, the steering mechanism, the braking device, or the like on the basis of the obtained information about the surroundings of the vehicle.

The microcomputer 7610 may generate three-dimensional distance information between the vehicle and an object such as a surrounding structure, a person, or the like, and generate local map information including information about the surroundings of the current position of the vehicle, on the basis of information obtained via at least one of the general-purpose communication I/F 7620, the dedicated communication I/F 7630, the positioning section 7640, the beacon receiving section 7650, the in-vehicle device I/F 7660, and the vehicle-mounted network I/F 7680. In addition, the microcomputer 7610 may predict danger such as collision of the vehicle, approaching of a pedestrian or the like, an entry to a closed road, or the like on the basis of the obtained information, and generate a warning signal. The warning signal may, for example, be a signal for producing a warning sound or lighting a warning lamp.

The sound/image output section 7670 transmits an output signal of at least one of a sound and an image to an output device capable of visually or auditorily notifying information to an occupant of the vehicle or the outside of the vehicle. In the example of FIG. 32, an audio speaker 7710, a display section 7720, and an instrument panel 7730 are illustrated as the output device. The display section 7720 may, for example, include at least one of an on-board display and a head-up display. The display section 7720 may have an augmented reality (AR) display function. The output device may be other than these devices, and may be another device such as headphones, a wearable device such as an eyeglass type display worn by an occupant or the like, a projector, a lamp, or the like. In a case where the output device is a display device, the display device visually displays results obtained by various kinds of processing performed by the microcomputer 7610 or information received from another control unit in various forms such as text, an image, a table, a graph, or the like. In addition, in a case where the output device is an audio output device, the audio output device converts an audio signal constituted of reproduced audio data or sound data or the like into an analog signal, and auditorily outputs the analog signal.

Incidentally, at least two control units connected to each other via the communication network 7010 in the example depicted in FIG. 32 may be integrated into one control unit. Alternatively, each individual control unit may include a plurality of control units. Further, the vehicle control system 7000 may include another control unit not depicted in the figures. In addition, part or the whole of the functions performed by one of the control units in the above description may be assigned to another control unit. That is, predetermined arithmetic processing may be performed by any of the control units as long as information is transmitted and received via the communication network 7010. Similarly, a sensor or a device connected to one of the control units may be connected to another control unit, and a plurality of control units may mutually transmit and receive detection information via the communication network 7010.

It is to be noted that it is possible to mount a computer program for realizing each function of the imaging device 100 or the distance measurement apparatus 200 described above on any control unit or the like. In addition, it is also possible to provide a computer-readable recording medium in which such a computer program is stored. The recording medium is, for example, a magnetic disk, an optical disk, a magneto-optical disk, a flash memory, or the like. In addition, the computer program described above may be distributed through a network, for example, without using a recording medium.

In the vehicle control system 7000 described above, it is possible to use the imaging device 100 or the distance measurement apparatus 200 described above as a light source steering section of LIDAR as an environment sensor, for example. In addition, it is possible for an optical computing unit that includes the imaging device 100 or the distance measurement apparatus 200 described above to perform image recognition at the imaging section. In a case where the imaging device 100 or the distance measurement apparatus 200 described above is used as a highly efficient and high-luminance projection device, it is possible to project lines or characters on the ground. Specifically, it is possible to display a line so that people outside a vehicle are able to see where the vehicle is passing when the vehicle rolls backward, or to display crosswalks with light when the vehicle gives way to pedestrians.

Moreover, at least some components of the imaging device 100 or the distance measurement apparatus 200 described above may be implemented in a module (for example, an integrated circuit module including one die) for the integrated control unit 7600 illustrated in FIG. 32. Alternatively, the imaging device 100 or the distance measurement apparatus 200 described above may be implemented by the plurality of control units of the vehicle control system 7000 illustrated in FIG. 32.

Although the present disclosure has been described hereinabove with reference to the embodiment, the modification examples thereof, and the application examples thereof, the present disclosure is not limited to the foregoing embodiment and the like, and may be modified in a variety of ways. It is to be noted that the effects described herein are mere examples. The effects of the present disclosure are not limited to the effects described herein. The present disclosure may have effects other than the effects described herein.

In addition, for example, the present disclosure may have the following configurations.

(1)

A photodetection device including
a plurality of pixels arranged two-dimensionally,
each of the pixels including:
   a photoelectric converter;
   a plurality of multipliers coupled in parallel to each other and coupled in series to the photoelectric converter; and
   a quench section coupled to the plurality of multipliers on a side opposite to a coupling side to the photoelectric converter.
      (2)

The photodetection device according to (1), in which each of the pixels further includes a metal wiring line that electrically couples respective portions of the plurality of multipliers on the quench section side to each other.

(3)

The photodetection device according to (2), further including a semiconductor substrate and an interlayer insulating film that is formed in contact with the semiconductor substrate, in which
in each of the pixels,
the photoelectric converter includes a semiconductor region of a predetermined electrical conduction type that is formed in a single region at a predetermined depth in the semiconductor substrate,
the plurality of multipliers is formed in a pn junction region that is formed in a region of the semiconductor substrate, the region being shallower than the photoelectric converter and being closer to the wiring layer, and
the metal wiring line is formed in the interlayer insulating film and in contact with the plurality of multipliers.
   (4)

The photodetection device according to (3), further including a signal processing substrate bonded to the semiconductor substrate with the interlayer insulating film interposed between the semiconductor substrate and the signal processing substrate, in which
the signal processing substrate includes a signal processor electrically coupled to the metal wiring line, and
the signal processor processes an output from the plurality of multipliers.
   (5)

The photodetection device according to (4), in which the interlayer insulating film and the signal processing substrate are electrically coupled to each other by joining copper pads provided on respective joint surfaces of the interlayer insulating film and the signal processing substrate to each other.

(6)

The photodetection device according to (3), in which, in each of the pixels, the plurality of multipliers is disposed at positions closer to a middle in a pixel region opposed to the photoelectric converter in a plan view.

(7)

The photodetection device according to (6), in which, in each of the pixels, the plurality of multipliers is disposed at positions in the pixel region excluding a center of the pixel region.

(8)

The photodetection device according to any one of (3) to (7), in which each of the pixels further includes, in the same layer as the plurality of multipliers in the semiconductor substrate, a separation section that separates the plurality of multipliers from each other.

(9)

The photodetection device according to (8), in which the separation section includes an ion implant formed in the semiconductor substrate.

(10)

The photodetection device according to (8), in which the separation section includes an STI (a shallow trench isolation) formed in the semiconductor substrate.

(11)

The photodetection device according to (1), further including a semiconductor substrate in which the photoelectric converter and the plurality of multipliers are formed, in which
each of the multipliers is formed in a region, of the semiconductor substrate, in which a first semiconductor region of a first electrical conduction type and a second semiconductor region of a second electrical conduction type join to each other, and
the semiconductor substrate further includes, in each of the pixels, a third semiconductor region of the first electrical conduction type that is in contact with each of a plurality of the first semiconductor regions.
   (12)

The photodetection device according to (11), in which a concentration of an impurity of the first electrical conduction type in the third semiconductor region is higher than a concentration of the impurity of the first electrical conduction type in the first semiconductor region.

(13)

The photodetection device according to (12), in which
the semiconductor substrate further includes, in each of the pixels, a fourth semiconductor region of the first electrical conduction type that is smaller in number than the multipliers, the fourth semiconductor region being in contact with the third semiconductor region and serving as a contact section, and
the concentration of the impurity of the first electrical conduction type in the third semiconductor region is lower than a concentration of the impurity of the first electrical conduction type in the fourth semiconductor region.
   (14)

An imaging device including
a plurality of pixels arranged two-dimensionally,
each of the pixels including:
   a photoelectric converter;
   a plurality of multipliers coupled in parallel to each other and coupled in series to the photoelectric converter; and
   a quench section coupled to the plurality of multipliers on a side opposite to a coupling side to the photoelectric converter.
      (15)

A distance measurement apparatus including
a photodetection device,
the photodetection device including a plurality of pixels arranged two-dimensionally,
each of the pixels including:
   a photoelectric converter;
   a plurality of multipliers coupled in parallel to each other and coupled in series to the photoelectric converter; and
   a quench section coupled to the plurality of multipliers on a side opposite to a coupling side to the photoelectric converter.

In the photodetection device according to the first aspect of the present disclosure, the imaging device according to the second aspect of the present disclosure, and the distance measurement apparatus according to the third aspect of the present disclosure, the plurality of multipliers coupled in parallel to each other is coupled in series to the photoelectric converter in each of the pixels. This makes it possible to reduce characteristic variations among the pixels, as compared with a case where a single multiplier is provided for each of the pixels.

The present application claims the benefit of International Patent Application No. PCT/JP2021/038918 filed with the Japan Patent Office on Oct. 21, 2021, the entire contents of which are incorporated herein by reference.

It should be understood by those skilled in the art that various modifications, combinations, sub-combinations and alterations may occur depending on design requirements and other factors insofar as they are within the scope of the appended claims or the equivalents thereof.

1. A photodetection device comprising
a plurality of pixels arranged two-dimensionally,
each of the pixels including:
a photoelectric converter;
a plurality of multipliers coupled in parallel to each other and coupled in series to the photoelectric converter; and
a quench section coupled to the plurality of multipliers on a side opposite to a coupling side to the photoelectric converter.

2. The photodetection device according to claim 1, wherein each of the pixels further includes a metal wiring line that electrically couples respective portions of the plurality of multipliers on the quench section side to each other.

3. The photodetection device according to claim 2, further comprising a semiconductor substrate and an interlayer insulating film that is formed in contact with the semiconductor substrate, wherein
in each of the pixels,
the photoelectric converter includes a semiconductor region of a predetermined electrical conduction type that is formed in a single region at a predetermined depth in the semiconductor substrate,
the plurality of multipliers is formed in a pn junction region that is formed in a region of the semiconductor substrate, the region being shallower than the photoelectric converter and being closer to the wiring layer, and
the metal wiring line is formed in the interlayer insulating film and in contact with the plurality of multipliers.

4. The photodetection device according to claim 3, further comprising a signal processing substrate bonded to the semiconductor substrate with the interlayer insulating film interposed between the semiconductor substrate and the signal processing substrate, wherein
the signal processing substrate includes a signal processor electrically coupled to the metal wiring line, and
the signal processor processes an output from the plurality of multipliers.

5. The photodetection device according to claim 4, wherein the interlayer insulating film and the signal processing substrate are electrically coupled to each other by joining copper pads provided on respective joint surfaces of the interlayer insulating film and the signal processing substrate to each other.

6. The photodetection device according to claim 3, wherein, in each of the pixels, the plurality of multipliers is disposed at positions closer to a middle in a pixel region opposed to the photoelectric converter in a plan view.

7. The photodetection device according to claim 6, wherein, in each of the pixels, the plurality of multipliers is disposed at positions in the pixel region excluding a center of the pixel region.

8. The photodetection device according to claim 3, wherein each of the pixels further includes, in a same layer as the plurality of multipliers in the semiconductor substrate, a separation section that separates the plurality of multipliers from each other.

9. The photodetection device according to claim 8, wherein the separation section includes an ion implant formed in the semiconductor substrate.

10. The photodetection device according to claim 8, wherein the separation section includes an STI (a shallow trench isolation) formed in the semiconductor substrate.

11. The photodetection device according to claim 1, further comprising a semiconductor substrate in which the photoelectric converter and the plurality of multipliers are formed, wherein
each of the multipliers is formed in a region, of the semiconductor substrate, in which a first semiconductor region of a first electrical conduction type and a second semiconductor region of a second electrical conduction type join to each other, and
the semiconductor substrate further includes, in each of the pixels, a third semiconductor region of the first electrical conduction type that is in contact with each of a plurality of the first semiconductor regions.

12. The photodetection device according to claim 11, wherein a concentration of an impurity of the first electrical conduction type in the third semiconductor region is higher than a concentration of the impurity of the first electrical conduction type in the first semiconductor region.

13. The photodetection device according to claim 12, wherein
the semiconductor substrate further includes, in each of the pixels, a fourth semiconductor region of the first electrical conduction type that is smaller in number than the multipliers, the fourth semiconductor region being in contact with the third semiconductor region and serving as a contact section, and
the concentration of the impurity of the first electrical conduction type in the third semiconductor region is lower than a concentration of the impurity of the first electrical conduction type in the fourth semiconductor region.

14. An imaging device comprising
a plurality of pixels arranged two-dimensionally,
each of the pixels including:
a photoelectric converter;
a plurality of multipliers coupled in parallel to each other and coupled in series to the photoelectric converter; and
a quench section coupled to the plurality of multipliers on a side opposite to a coupling side to the photoelectric converter.

15. A distance measurement apparatus comprising
a photodetection device,
the photodetection device including a plurality of pixels arranged two-dimensionally,
each of the pixels including:
a photoelectric converter;
a plurality of multipliers coupled in parallel to each other and coupled in series to the photoelectric converter; and
a quench section coupled to the plurality of multipliers on a side opposite to a coupling side to the photoelectric converter.
